(19) United States
(12) Patent Application Publication
(10) Pub. No.: US 2024/0332054 A1
(43) Pub. Date: Oct. 3, 2024

(54) ROTATIONAL INDEXER WITH WAFER EDGE GRIP

(71) Applicant: Lam Research Corporation, Fremont, CA (US)

(72) Inventor: Eric Bramwell Britcher, San Jose, CA (US)

(21) Appl. No.: 18/622,599

(22) Filed: Mar. 29, 2024

Related U.S. Application Data
(60) Provisional application No. 63/493,681, filed on Mar. 31, 2023.

(51) Int. Cl. H01L 21/677; H01L 21/687

(52) U.S. Cl. CPC H01L 21/67706; H01L 21/68742; H01L 21/68764; H01L 21/68771

(57) ABSTRACT

A rotational indexer is provided that may be rotated to move semiconductor wafers or other items between various stations arranged in a circular array; the items being moved may be supported by arms of the indexer during such movement. The rotational indexer may be further configured to also cause the items being moved to rotate about other rotational axes to cause rotation of the items relative to the arms supporting them.

### RELATED APPLICATION(S)

An Application Data Sheet is filed concurrently with this specification as part of the present application. Each application that the present application claims benefit of or priority to as identified in the concurrently filed Application Data Sheet is incorporated by reference herein in its entirety and for all purposes.

### BACKGROUND

Some semiconductor processing tools process multiple wafers within a common chamber simultaneously and use a rotational indexer to move wafers from processing station to processing station within the chamber. In such semiconductor processing tools, the processing stations may generally be laid out such that the wafer center points are equidistantly spaced along a circular path. A rotational indexer that includes a central hub and multiple arms that radiate outwards from that central hub may be used to move the wafers from station to station; the end of the arms may have some form of wafer support that may be used to support wafers being moved by the indexer. Moving the wafers from station to station using such a device is referred to as “indexing” the wafers. Generally, the number and angular spacing of the arms on the indexer will correspond with the number and angular spacing of the processing stations about the circular path's center point. For example, in a four-station chamber, there may be four arms on the indexer, each oriented at 90° from the adjacent arms. Wafers may be placed on the arms and the central hub and the arms connected thereto may be rotated as a unit about the center point of the circular path, thereby moving the wafers from station to station.

U.S. Pat. No. 10,109,517 describes an indexer with additional rotational axes in which the wafer supports located at the ends of the indexer arms that support the wafers are configured to rotate relative to the indexer arms. Disclosed herein are further improvements to such a rotational indexer with additional rotational axes.

### SUMMARY

Details of one or more implementations of the subject matter described in this specification are set forth in the accompanying drawings and the description below. Other features, aspects, and advantages will become apparent from the description, the drawings, and the claims.

In some implementations, an apparatus may be provided that includes a rotational indexer. The rotational indexer may include a base, a first hub, and N indexer arm assemblies. Each indexer arm assembly may include a) a wafer support and b) an indexer arm having a proximal end fixedly connected with the rotatable first hub and a distal end that supports the wafer support for that indexer arm. Each wafer support may be configured to be rotatable about a corresponding rotational axis located at the distal end of the indexer arm that supports that wafer support and between a first rotational position relative to the indexer arms and a second rotational position relative to the indexer arms. The first hub may be configured to be rotatable about a center axis and between at least a first angular position relative to the base and a second angular position relative to the base. The first angular position and the second angular position may be 360°/N apart, each wafer support may have at least three corresponding wafer edge contact interfaces including a corresponding first wafer edge contact interface, a corresponding second wafer edge contact interface, and a corresponding third wafer edge contact interface, and each wafer edge contact interface may, when the wafer supports are in the first rotational positions relative to the indexer arm assemblies and the wafer supports are viewed along a direction parallel to the center axis, be located outside of a plurality of circular reference regions that each have a center positioned along a circular path centered on the center axis, are each positioned between a different adjacent pair of the indexer arm assemblies, and that each have a diameter D. Furthermore, each wafer edge contact interface may, when the wafer supports are in the second rotational positions relative to the indexer arm assemblies and the wafer supports are viewed along a direction parallel to the center axis, located at least partially within one of the circular reference regions.

In some implementations, the first wafer edge contact interfaces may, when the wafer supports are in the first rotational positions relative to the indexer arm assemblies and the wafer supports are viewed along a direction parallel to the center axis, all be located at least partially within a regular N-sided polygonal region that is circumscribed about the circular path and centered on the center axis. In such implementations, each corner of the regular polygonal region may lie along an axis that passes through the center axis and one of the rotational axes of the wafer supports, the second wafer edge contact interfaces and the third wafer edge contact interfaces may, when the wafer supports are in the first rotational positions relative to the indexer arm assemblies and the wafer supports are viewed along a direction parallel to the center axis, all be located at least partially outside of the regular N-sided polygonal region, the first wafer edge contact interfaces and the second wafer edge contact interfaces may, when the wafer supports are in the second rotational positions relative to the indexer arm assemblies and the wafer supports are viewed along a direction parallel to the center axis, all be located at least partially outside of the regular N-sided polygonal region, and the third wafer edge contact interfaces may, when the wafer supports are in the second rotational positions relative to the indexer arm assemblies and the wafer supports are viewed along a direction parallel to the center axis, all be located at least partially within the regular N-sided polygonal region.

In some implementations, the first wafer edge contact interfaces may, when the wafer supports are in the first rotational positions relative to the indexer arm assemblies, all be located within the regular N-sided polygonal region, the second wafer edge contact interfaces and the third wafer edge contact interfaces may, when the wafer supports are in the first rotational positions relative to the indexer arm assemblies, all be located outside of the regular N-sided polygonal region, the first wafer edge contact interfaces and the second wafer edge contact interfaces may, when the wafer supports are in the second rotational positions relative to the indexer arm assemblies, all be located outside of the regular N-sided polygonal region, and the third wafer edge contact interfaces may, when the wafer supports are in the second rotational positions relative to the indexer arm assemblies, all be located within the regular N-sided polygonal region.

In some implementations, each wafer support may include a corresponding top surface, and each wafer edge contact interface may include a corresponding wafer support surface that is positioned at an elevation lower than the corresponding top surface of the wafer support having that wafer edge contact interface.

In some implementations, each wafer edge contact interface may have a corresponding first protrusion that extends upward from the corresponding wafer support surface of that wafer edge contact interface.

In some implementations, for each wafer support, the corresponding first protrusion of the first wafer edge contact interface of that wafer support may, when the wafer supports are in the second rotational positions relative to the indexer arm assemblies and the wafer supports are viewed along a direction parallel to the center axis, be located within one of the circular reference regions and the corresponding first protrusions of the second wafer edge contact interface and the third wafer edge contact interface of that wafer support may, when the wafer supports are in the second rotational positions relative to the indexer arm assemblies and the wafer supports are viewed along a direction parallel to the center axis, be located within a different one of the circular reference regions adjacent to the circular reference region in which the corresponding first protrusion of that first wafer edge contact interface is located.

In some implementations, each wafer edge contact interface may have an obliquely sloped surface in between the corresponding top surface of the wafer support having that wafer edge contact interface and the wafer support surface of that wafer support.

In some implementations, each circular reference region may define a reference axis that is parallel to the center axis and passes through the center of that circular reference region, and each obliquely sloped surface may be oriented such that a normal to that obliquely sloped surface is oriented towards one of the reference axes.

In some implementations, each wafer edge contact interface may include a corresponding roller that is configured to rotate about a corresponding roller axis relative to the wafer support having that wafer edge contact interface.

In some implementations, each circular reference region may define a reference axis that is parallel to the center axis and passes through the center of that circular reference region, the roller axes may all be parallel to a reference plane that is perpendicular to the center axis, and each roller axis may, when the wafer supports are in the second rotational positions relative to the indexer arm assemblies, be perpendicular to a normal of one of the reference axes.

In some implementations, the corresponding first wafer edge contact interface, the corresponding second wafer edge contact interface, and the corresponding third wafer edge contact interface of each wafer support may all be a distance more than one half of D from the rotational axis of that wafer support.

In some implementations, the apparatus may further include a controller configured to (a) cause the wafer supports to rotate to the second rotational positions relative to the indexer arms from the first rotational positions relative to the indexer arms while the first hub is in the first angular position relative to the base, (b) cause the first hub to rotate from the first angular position relative to the base to the second angular position relative to the base while simultaneously keeping the wafer supports in the second rotational positions relative to the indexer arms, and (c) cause the wafer supports to rotate to the first rotational positions relative to the indexer arms from the second rotational positions relative to the indexer arms while the first hub is in the second angular position relative to the base.

In some implementations, the apparatus may further include N pedestals arranged in a circular array about the center axis. In such implementations, each pedestal may include a corresponding lift pin mechanism configured to move a set of lift pins for that pedestal between at least a first state, a second state, and a third state relative to that pedestal. Additionally, the lift pins may be lower in the first state and the third state than in the second state, and the controller may be further configured to cause the lift pins to: be in the first state prior to (a), be in the second state after (a) and prior to (b), and be in the third state after (b) and prior to (c).

In some implementations, the first state and the third state may be the same.

In some implementations, the lift pin mechanism of each pedestal may be further configured to move the set of lift pins for that pedestal between at least a fourth state and a fifth state relative to that pedestal, the lift pins may be higher in the fourth state than in the fifth state, and the controller may be further configured to (d) cause the lift pins to be in the fourth state, (e) cause the first hub to rotate from the first angular position relative to the base to the second angular position relative to the base while the lift pins are in the fourth state, (f) cause the lift pins to move into the fifth state, (g) cause the wafer supports to rotate relative to the indexer arms while the lift pins are in the fourth state, (h) cause the lift pins to move into the fifth state, and (i) cause the first hub to rotate from the second angular position relative to the base to the first angular position relative to the base while the lift pins are in the fifth state.

In some implementations, each wafer support may have a plurality of second protrusions extending upward from the top surface thereof.

In some implementations, each wafer support may be shaped so as to be rotatable through 360°/N while the lift pins are in the fifth state without contacting any of the lift pins.

In some implementations, N may equal 4.

In some implementations, an apparatus may be provided that includes a rotational indexer. The rotational indexer may include a base, a first hub, and N indexer arm assemblies, each indexer arm assembly including a) a wafer support and b) an indexer arm having a proximal end fixedly connected with the rotatable first hub and a distal end that supports the wafer support for that indexer arm. In such implementations, each wafer support may be configured to be rotatable about a corresponding rotational axis located at the distal end of the indexer arm that supports that wafer support and between at least a first rotational position relative to the indexer arms and a second rotational position relative to the indexer arms, the first hub may be configured to be rotatable about a center axis and between at least a first angular position relative to the base and a second angular position relative to the base, the first angular position and the second angular position may be 360°/N apart, and each wafer support may be configured to support a semiconductor wafer of diameter D from below when the semiconductor wafer is placed on that wafer support and has one or more corresponding wafer edge contact interfaces configured to limit radial outward movement of the semiconductor wafer due to centrifugal force when the first hub is caused to rotate about the center axis at a first angular rate while the semiconductor wafer is supported by that wafer support and that wafer support is in the second relative rotational position.

In some implementations, the one or more corresponding wafer edge contact interfaces of each wafer support may limit radial outward movement of the semiconductor wafer by way of at least two points of contact between the one or more corresponding wafer edge contact interfaces and the semiconductor wafer due to centrifugal force when the first hub is caused to rotate about the center axis at the first angular rate while the semiconductor wafer is supported by that wafer support and that wafer support is in the second rotational position.

In some implementations, the one or more corresponding wafer edge contact interfaces of each wafer support may include at least a first wafer edge contact interface and a second wafer edge contact interface.

In some implementations, for each wafer support, the corresponding first wafer edge contact interface and the corresponding second wafer edge contact interface may both be positioned within a 90° sector of arc relative to the corresponding rotational axis of that wafer support.

In some implementations, for each wafer support, the corresponding first wafer edge contact interface and the corresponding second wafer edge contact interface may both be positioned within a 60° sector of arc relative to the corresponding rotational axis of that wafer support.

In some implementations, for each wafer support, the corresponding first wafer edge contact interface and the corresponding second wafer edge contact interface may both be positioned within a 30° sector of arc relative to the corresponding rotational axis of that wafer support.

In some implementations, each wafer edge contact interface may include a corresponding roller configured to rotate relative to the indexer arms.

In some implementations, each roller may be configured to rotate relative to the indexer arms and about a corresponding roller axis that is parallel to a reference plane that is perpendicular to the center axis.

In some implementations, each roller of each wafer support may have a surface closest to the corresponding rotational axis for that wafer support that is located at a distance from the corresponding rotational axis for that wafer support that is substantially equal to one half of D.

In some implementations, each wafer support may include a plurality of protrusions extending upward from an upper surface of that wafer support and configured to support the semiconductor wafer of diameter D from below when the semiconductor wafer is placed on that wafer support.

In some implementations, N may equal 4.

In some implementations, the apparatus may further include a first set of lift pins associated with a first pedestal of the N pedestals. In such implementations, the wafer supports, when in the first rotational position, may be oriented such that the first wafer edge contact interface and the second wafer edge contact interface of a first wafer support of the N wafer supports lies within a circle centered on the center axis and passing through at least one of the lift pins in the first set of lift pins, and the wafer supports, when in the second rotational position, are oriented such that the first wafer edge contact interface and the second wafer edge contact interface of the first wafer support lie outside of the circle.

In some implementations, the apparatus may further include a controller configured to a) cause the first set of lift pins and the first pedestal to enter a first state in which the first set of lift pins protrude from an upper surface of the first pedestal, b) cause the N wafer supports to rotate into the first rotational positions after (a), c) cause the first set of lift pins and the first pedestal to enter a second state in which the first set of lift pins do not protrude from the upper surface of the first pedestal, and d) cause the first hub to rotate about the center axis at least after (b) is started such that each wafer support is above a corresponding one of the pedestals prior to (c).

In some implementations, the controller may be further configured to cause at least part of (b) and (d) to occur simultaneously.

In some implementations, the controller may be further configured to e) cause, after (c), the first hub to further rotate about the center axis by 360°/N, and f) cause, after (e), a second set of lift pins associated with a second pedestal of the N pedestals to enter a first state in which the second set of lift pins protrude from an upper surface of the second pedestal.

In some implementations, the controller may be further configured to cause the wafer supports to be in the second rotational positions during (e).

In some implementations, the controller may be further configured to g) cause the N wafer supports to rotate about the corresponding rotational axes relative to the indexer arms in between (c) and (f).

Other features, aspects, and advantages will become apparent from the description, the drawings, and the claims. Note that the relative dimensions of the following figures may not be drawn to scale.

### BRIEF DESCRIPTION OF THE DRAWINGS

The various implementations disclosed herein are illustrated by way of example, and not by way of limitation, in the figures of the accompanying drawings, in which like reference numerals refer to similar elements.

FIG. 1 is a schematic diagram showing wafer rotation in a conventional rotational indexer.

FIG. 2 is a schematic diagram showing wafer rotation supported by a rotational indexer with additional rotational axes, as discussed herein.

FIG. 3 depicts a top view of part of an example semiconductor processing tool having a rotational indexer that is an example of the rotational indexers discussed herein.

FIG. 4 depicts a perspective, partially-exploded view of the example rotational indexer of FIG. 3.

FIG. 5 depicts a side section view of the example rotational indexer of FIG. 3.

FIG. 6 depicts a detail view of the center of the example rotational indexer of FIG. 3 with some additional components removed.

FIG. 7 depicts a detail top view of a portion of an example second hub and tie-rods, showing overlap between two tie-rods in a particular configuration.

FIG. 8 depicts a detail top view of a portion of another example second hub and tie-rods, showing an alternate tie-rod design.

FIGS. 9-A through 9-E show the example rotational indexer of FIG. 3 through various states of actuation of the rotatable wafer supports located at the distal ends of the indexer arms.

FIG. 10 is a flow diagram for an example technique for operating a rotational indexer according to some examples described herein.

FIGS. 11-1 through 11-5 show different stages of movement of an example rotational indexer having rotatable wafer supports that may be used to support wafers along the wafers' edges.

FIG. 12-1 depicts a perspective view of the rotational indexer of FIGS. 11-1 through 11-5.

FIG. 12-2 depicts a detail view of the area enclosed in a heavy black circle in FIG. 12-1.

FIG. 13-1 depicts an alternate wafer edge contact interface design and is similar to FIG. 12-1.

FIG. 13-2 depicts a detail view of the area enclosed in a heavy black circle in FIG. 13-1.

FIG. 14-1 depicts a side view of the rotational indexer of FIGS. 11-1 through 11-2.

FIGS. 14-2 through 14-5 depict detail views of the circled portion of FIG. 14-1 during various stages of lift pin operation.

FIGS. 15-1 through 15-9 depict a version of the rotational indexer of FIGS. 11-1 through 11-5 that may also be used to provide wafer rotation relative to the indexer arms, similar to the functionality provided by the rotational indexer of FIG. 3.

FIG. 16 depicts a top view of one of the wafer supports of FIGS. 15-1 through 15-9 that illustrates some of the features of such wafer supports.

FIG. 17 depicts a perspective view of a rotational indexer featuring rotatable wafer supports that are each configured to separately support, and prevent radial slippage of, a semiconductor wafer during indexing operations.

FIG. 17′ depicts a detail view of the portion of FIG. 17 inside the circled region.

FIGS. 18-1 through 18-9 depict top views of the rotational indexer of FIG. 17 in various states of operation.

FIG. 19 depicts a system diagram for an example controller for the rotational indexer of FIG. 3.

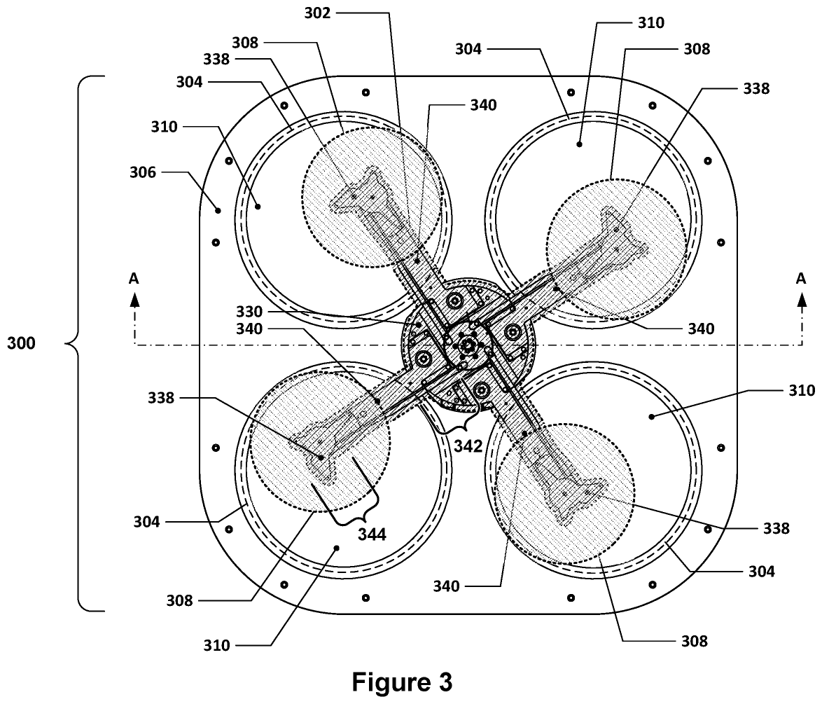

FIGS. 3 through 18-9 are drawn to-scale within each Figure, although the scale may vary from Figure to Figure. The Figures depict only an example of the concepts discussed herein, and it will be readily appreciated that the concepts discussed herein may be implemented in a large number of alternate implementations, all of which are considered to be within the scope of this disclosure.

### DETAILED DESCRIPTION

Importantly, the concepts discussed herein are not limited to any single aspect or implementation discussed herein, nor to any combinations and/or permutations of such aspects and/or implementations. Moreover, each of the aspects of the present invention, and/or implementations thereof, may be employed alone or in combination with one or more of the other aspects and/or implementations thereof. For the sake of brevity, many of those permutations and combinations will not be discussed and/or illustrated separately herein.

The rotational indexers with additional rotational axes disclosed herein differ from conventional rotational indexers in that they possess additional degrees of rotational freedom at the distal ends of the indexer arms. For example, in a conventional indexer, the only rotation that is provided is of the entire hub/arm structure about the center axis of the indexer—as a result, when the hub/arm structure is rotated, the items carried at the end of each arm rotate in the same manner about the same rotational axis. This causes the items, e.g., semiconductor wafers, to maintain the same orientation with respect that that rotational axis—for example, the same portion of each item will always be closest to the rotational center axis.

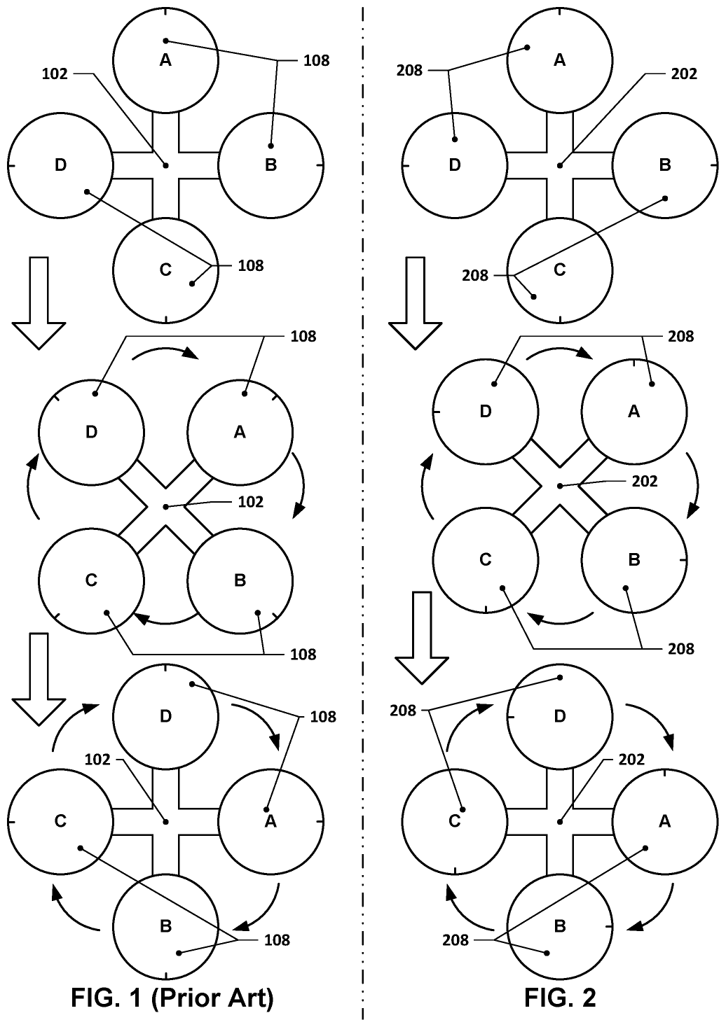

This may be seen in FIG. 1, which is a schematic diagram showing wafer rotation in a conventional rotational indexer. Three indexer positions are shown—the starting position is at top, an intermediate position in the middle, and a terminal position at the bottom (this is for a single set of wafer movements from the positions shown at top to the positions shown at bottom). Each wafer 108 has a short line/mark at the outermost edge; then the indexer 102 is rotated, all four wafers 108 rotate about the rotational axis of the indexer 102. As a result, the edges of the wafers 108 with the lines/marks remain the edges of the wafers furthest from the rotational axis of the indexer 102 throughout the rotational movement. Put another way, the orientation of each wafer relative to the arm that supports it remains unchanged.

Indexers according to the present disclosure, however, are able to provide for additional degrees of rotational motion such that the orientation of the wafers relative to the arms can be altered during, before, and/or after rotational movement of the indexer. As a result, the edges or portions of the edges of the wafers closest to the indexer rotational axis may be changed so that different sides of the wafers may be located closest to the rotational center of the indexer at each station. Thus, such indexers may not only “index” the wafer between different positions, but may also “spin” the wafers during, before, or after such “indexing” movement—thus, such indexers may be referred to as “Spindexers” or “Spindex” (usage of such names may be reserved by Applicant as a trade name or trademark, and the recitation herein of such names is not to be taken as surrender of such protected status).

This may be seen in FIG. 2, which is a schematic diagram showing wafer rotation supported by a rotational indexer with additional rotational axes, as discussed above and elsewhere herein. FIG. 2 has a similar layout to FIG. 1, with three positions of a rotational indexer 202 shown, along with wafers 208. As can be seen in the topmost position, the short lines/marks along the outer edges of the wafers 208 are all furthest from the rotational center of the indexer 202 and are generally aligned with the arms of the indexer 202. In the middle position, the indexer 202 has rotated 45° clockwise, but the wafers 208 have also been rotated by the same amount in a counterclockwise direction. As a result, the orientation of each wafer 208 relative to the arm that supports it changes, with the wafers 208 being rotated by 90° relative to the arms in the lower position. This causes different edges of the wafers 208 to be furthest from the rotational center of the indexer 202 than in the top position in FIG. 2.

FIG. 3 depicts a top view of part of an example semiconductor processing tool having a rotational indexer that is an example of the rotational indexers discussed herein. In FIG. 3, a semiconductor processing tool 300 is shown that has a processing chamber 306 that includes four semiconductor processing stations 304, each of which has a pedestal 310. The semiconductor processing stations 304 are arranged in a radial or circular array about a center axis, and a rotational indexer 302 is provided that is configured to rotate about that center axis. The rotational indexer 302 may have a plurality of indexer arms 340, e.g., four indexer arms in this example, that are attached to a first hub 330 at a proximal end 342 such that when the first hub 330 is rotated about the center axis, the arms 340 rotate with it. Distal ends 344 of the indexer arms 340 may be provided with wafer supports 338, each of which may be configured to be rotatable relative to the indexer arm 340 that supports it and about a rotational axis that is located at that distal end 344. Each wafer support 338 may be configured to support a wafer 308 (wafers 308 are shown in dotted outline to allow components of the indexer arms to be more easily seen) during movement of the wafers 308 between processing stations 304.

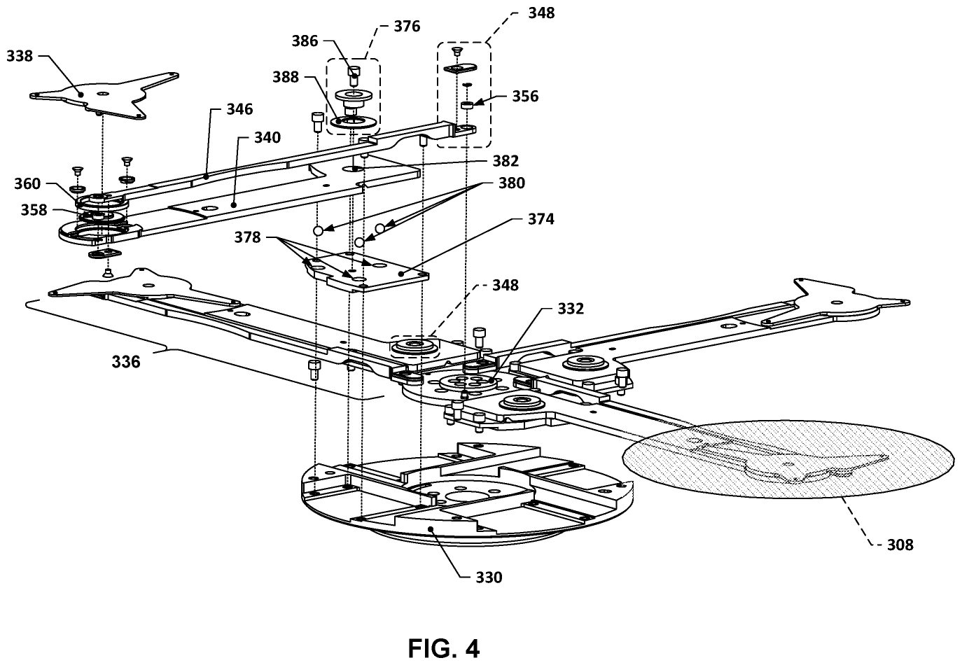

FIG. 4 depicts a perspective, partially-exploded view of the example rotational indexer of FIG. 3. As can be seen in FIG. 4, one of the indexer arm assemblies 336 is shown in an exploded fashion; the other indexer arm assemblies 336 are shown in their assembled states as they would be arranged when fastened to a first hub 3430 (only one indexer arm assembly 336 is numbered). For reference, one of the indexer arm assemblies s is shown supporting a wafer 308, which is shown as partially transparent and with a dotted edge so as to not obscure features of the indexer arm assembly 336. Each indexer arm assembly 336 may include an indexer arm 340 that has a proximal end 342 that is connected, either directly or indirectly, with the first hub 330. Each indexer arm assembly 336 may also include a wafer support 338 that is rotatably mounted to the distal end 344 of the indexer arm 340. The wafer support, may, for example, be a small plate or platform that is configured to support a semiconductor wafer. The wafer support 338 may be able to rotate about a rotational axis of the wafer support, e.g., an axis that passes through the center of a semiconductor wafer that the wafer support 338 is designed to support, relative to the indexer arm 340 that supports it.

Generally speaking, the first hub 330, and the indexer arm assemblies 336 attached thereto, may be rotatable about a rotational axis of the first hub 330 to move wafers 308 from station to station. In addition to such rotation, the indexer 302 may also include an actuation mechanism that may be configured to cause all of the wafer supports 338 to simultaneously rotate relative to the indexer arms 340 and about respective rotational axes located in the distal ends 344 of the indexer arms 340. The actuation mechanism may be further configured to cause all of the wafer supports 338 to rotate simultaneously responsive to a single mechanical input. For example, a common rotational drive shaft located in the center of the rotational indexer 302 may be connected with drive shafts extending along each indexer arm 340 through bevel or other types of gearing; each drive shaft may, in turn cause the wafer supports 338 to rotate responsive to rotation of the drive shaft. In an alternative implementation, flexible belts, e.g., thin stainless steel belts, may be looped between pulleys attached to each wafer support 338 and a common rotational drive shaft so that rotation of the drive shaft relative to the indexer arms 340 causes the wafer supports 338 to also rotate relative to the indexer arms 340.

In some implementations, the actuation mechanism may utilize an array of movable linkages to cause the wafer supports 338 to rotate relative to the indexer arms 340. The example rotational indexer 302 in FIGS. 3 and 4 includes such a mechanism. As can be seen in FIG. 4, the actuation mechanism of the rotational indexer 302 includes a second hub 332. The second hub 332 may be configured to rotate about the same rotational axis that the first hub 330 is configured to rotate about. The first hub 330 and the second hub 332 may be independently rotatable such that the first hub 330 and the second hub 332 may be placed in a variety of different angular orientations relative to one another.

In such an actuation mechanism, each indexer arm assembly 336 may further include a tie-rod 346 that extends along the length of the corresponding indexer arm 340. Each tie-rod 346 may have a proximal end 348 that is rotatably connected with the second hub 332 via a first rotational interface 356 and a distal end 350 that is rotatably connected with a corresponding wafer support 338 via a second rotational interface 358. The first rotational interface 356 and the second rotational interfaces 358 may be located some distance from the center axis 352 and the rotational axes 354, respectively, so as to define a moment arm about each axis. The rotational axes 354 may, for example, be rotational axes for third rotational interfaces 360, which may rotatably couple the wafer supports 338 to their respective indexer arms 340.

When relative rotational motion between the first hub 330 and the second hub 332 about the center axis 352 is induced, the tie-rods 346 are moved in a generally radial manner (there is some tangential motion as well as the tie-rods 346 move away from and then closer to the adjacent indexer arms 340) that causes the wafer supports 338 to which they are rotatably connected to rotate about the rotational axes 354 relative to the indexer arms 340 to which the wafer supports 338 are attached. When the relative rotational motion between the first hub 330 and the second hub 332 is non-existent, then the wafer supports 338 will remain fixed in position relative to the indexer arms 340.

Such a rotational indexer may thus be driven so as to provide rotation of the wafer supports 338 relative to the indexer arms 340 without any corresponding rotation of the indexer arms 340 (by rotating the second hub 332 while keeping the first hub 330 stationary), rotation of the indexer arms 340 about the center axis 352 without any corresponding rotation of the wafer supports 338 relative to the indexer arms 340 (by rotating the first hub 330 and the second hub 332 in synchrony (and by the same amount), and rotation of the indexer arms 340 about the center axis 352 with simultaneous rotation of the wafer supports 338 relative to the indexer arms 340 (by rotating the first hub 330 not in synchrony with the second hub 332, e.g., by rotating the first hub 330 about the center axis 352 while keeping the second hub 332 stationary or by rotating the first hub 330 and the second hub 332 about the center axis 352 at different rates).

In some implementations, such as in the depicted example, the distances between each of the first rotational interfaces 356 and the center axis 352 may be equal to the distances between each of the second rotational interfaces 358 and the corresponding rotational axes 354 may be equal such that the moment arms defined by the tie-rods 346 are the same. In such an implementation, the relative rotation between the wafer supports 338 and the indexer arms 340 may be the same as the relative rotation between the first hub 330 and the second hub 332. Such an implementation may be particularly efficient since this may cause each wafer to be kept in the same absolute orientation (relative to the semiconductor processing tool, for example) regardless of which processing station that wafer is moved to by the rotational indexer 302 when each wafer transfer from one station to the next is accomplished by rotating only the first hub 330 while keeping the second hub 332 stationary.

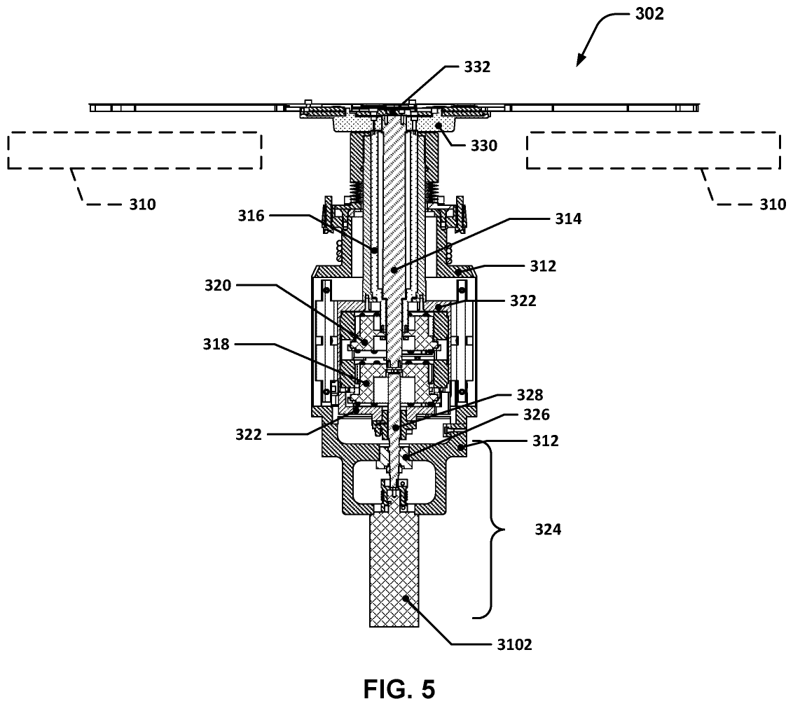

FIG. 5 depicts a side section view of the example rotational indexer of FIG. 3. As shown in FIG. 5, the rotational indexer 302 may include a base 312 that may be mounted in the semiconductor processing tool 300. The base 312 may house various systems that may be used to actuate the rotational indexer 302. For example, the base 312 may have a motor housing 322 that may house a first motor 318 and a second motor 320. The first motor 318 may be connected with the first hub 330 by a first shaft 314, and the second motor 320 may be connected with the second hub 332 by a second shaft 316. Thus, the first motor 318 may be actuated to rotate the first hub 330, and the second motor may be actuated to rotate the second hub 332.

In some implementations, the rotational indexer 302 may also be configured for vertical movement as well. For example, a z-axis drive system 324 may be provided to drive the motor housing 322, the first motor 318, the second motor 320, the first hub 330, and the second hub 332 up and down vertically, thereby causing the indexer arms 340 to move vertically. The z-axis drive system 324 may include, in some implementations, a third motor 3102 configured to rotate a threaded shaft 328 that passes through a ball-screw 326 attached to the motor housing 322, thereby causing vertical movement when the third motor 3102 is actuated.

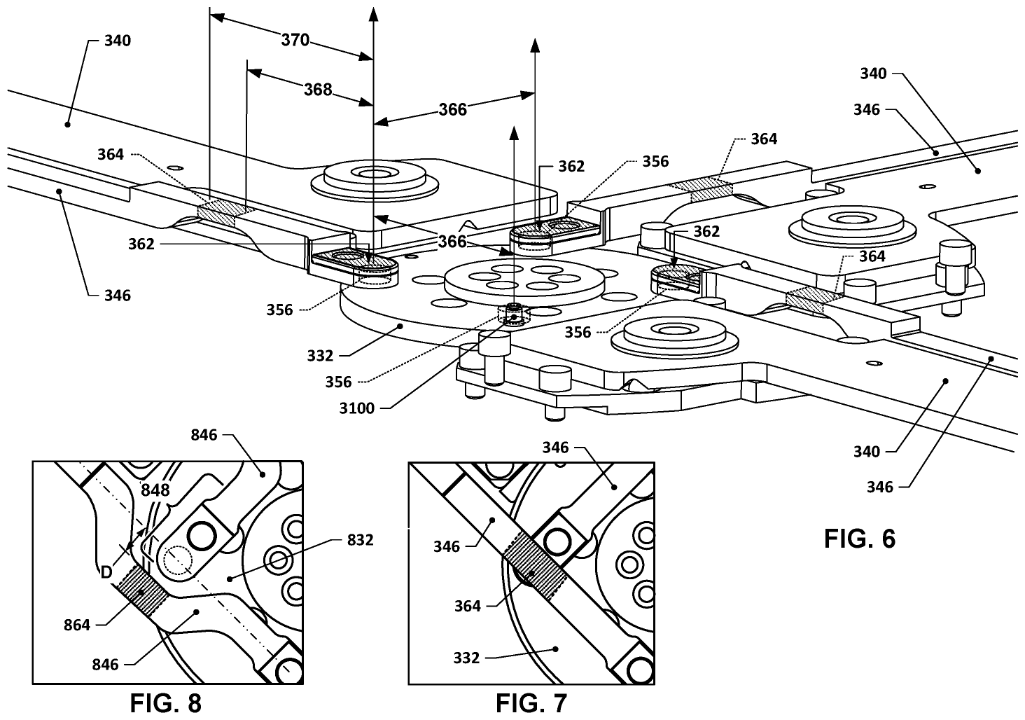

In implementations having an actuation mechanism such as that discussed above in which the wafer supports 338 rotate relative to the indexer arms 340 about the rotational axes 354 by the same amount that the first hub 330 and the second hub 332 rotate relative to one another, the first rotational interfaces 356 that link the tie-rods 346 to the second hub 332 may, during such relative rotation between the first hub 330 and the second hub 332, be moved so as to be in the same position as an adjacent first rotational interface 356 was in prior to such rotation. FIG. 6 depicts a detail view of the center of the example rotational indexer of FIG. 3, which is an example of such a rotational indexer, with some additional components removed, e.g., with an indexer arm assembly 336, the first hub 330 removed, and various other components omitted.

As shown in FIG. 6, the tie-rods 346 may further include an offset region 364. The offset regions 364 may extend along the length of the tie-rods 346, i.e., in a longitudinal direction, for some distance. Each offset region 364 may be considered to start at location that is a first longitudinal distance 368 from the rotational center axis of the first rotational interface 356 for that offset region's tie-rod 346 and may considered to end at a location that is a second longitudinal distance 370 from the rotational center axis of the first rotational interface 356 for that offset region's tie-rod 346. Generally speaking, the first longitudinal distance 368 and the second longitudinal distance 370 may be selected so as to be less than and greater than, respectively, a first distance 366 between the rotational center axes of adjacent first rotational interfaces 356. As shown in FIG. 6, the first rotational interfaces 356 are represented by dotted outlines, and a post 3100 that interfaces with the missing first rotational interface 356 is depicted (the first rotational interfaces 356 in this example are rotational bearing assemblies, e.g., ball bearings, roller bearings, or other similar devices).

Each offset region 364 may be configured such that the tie-rod 346 of which it is part does not contact or collide with the proximal end 348 of an adjacent tie-rod 346 during rotational motion as described above, i.e., when each first rotational interface 356 is advanced in position to the location last occupied by an adjacent first rotational interface 356. Thus, the tie-rod 346 may, in the offset region 364, include a jog or other deviation from the general shape of the tie-rod 346.

In the implementation shown in FIG. 6, for example, the offset region 364 includes a lowermost surface 390 (not shown in FIG. 6) that is positioned at an elevation that is, when the rotational indexer is positioned with the center axis 352 in a vertical orientation and with the base 312 below the indexer arms 340, higher than an uppermost surface 362 of the proximal end 348 of the adjacent tie-rod 346 directly above the first rotational interface 356 of that adjacent tie-rod 346. This allows the proximal ends 348 of the tie-rods 346 to pass underneath the offset regions 364 (without any of the tie-rods 346 contacting each other) of the adjacent tie-rods 346 when each first rotational interface 356 is advanced in position to the location last occupied by an adjacent first rotational interface 356. FIG. 7 is a detail view showing how the proximal end 348 of a tie-rod 346 may pass underneath the offset region 364 of another tie-rod 346.

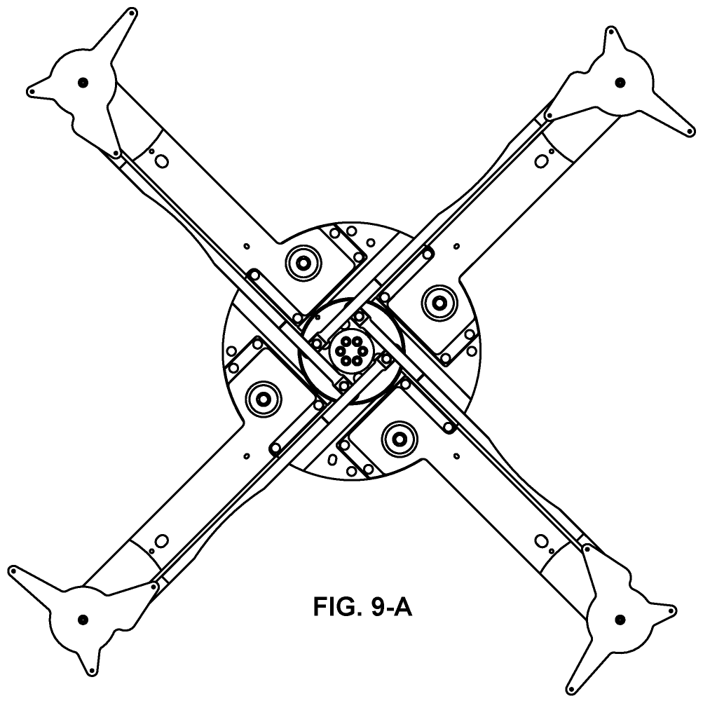

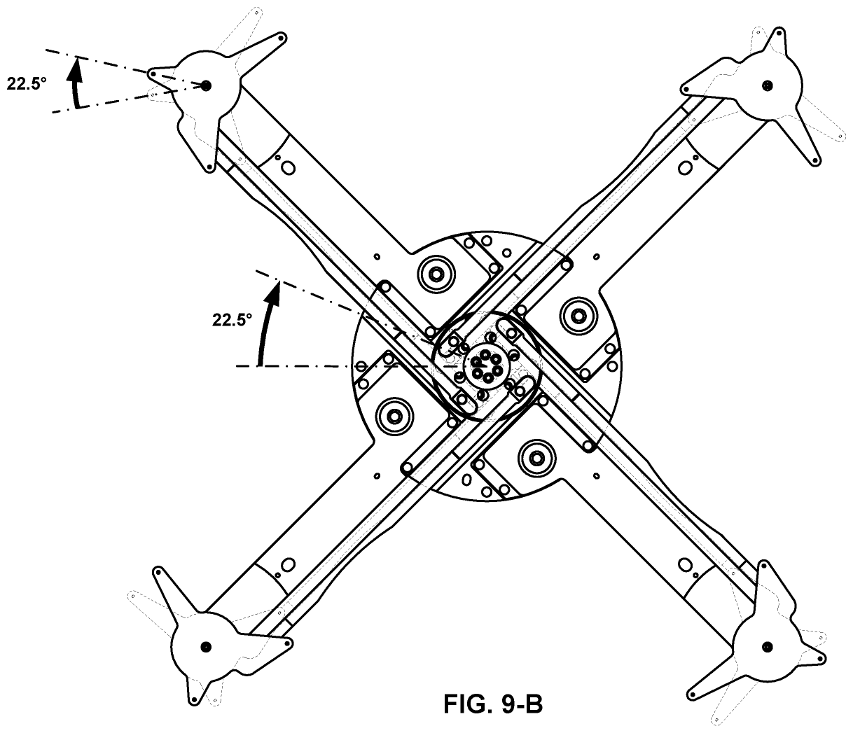

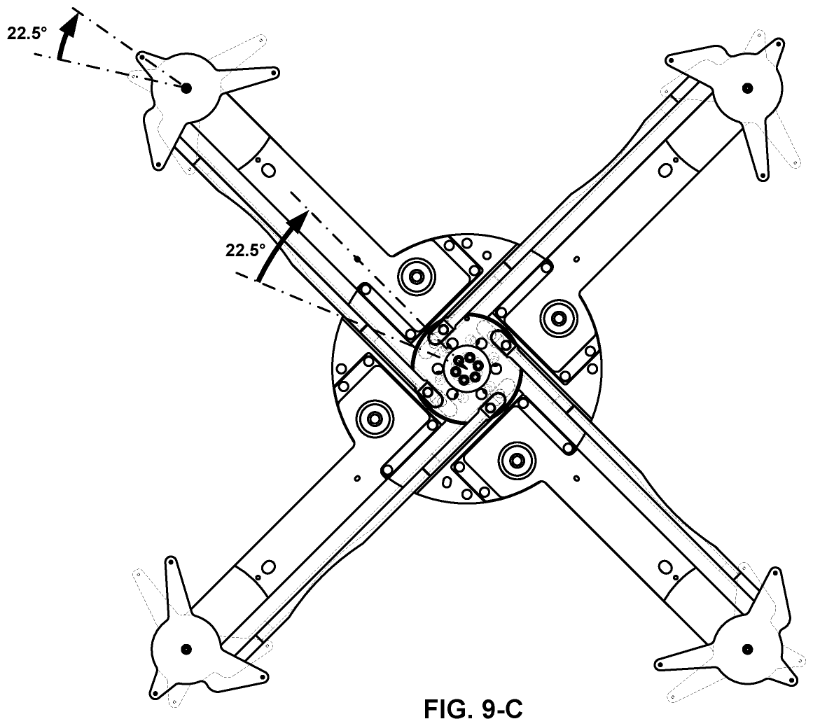

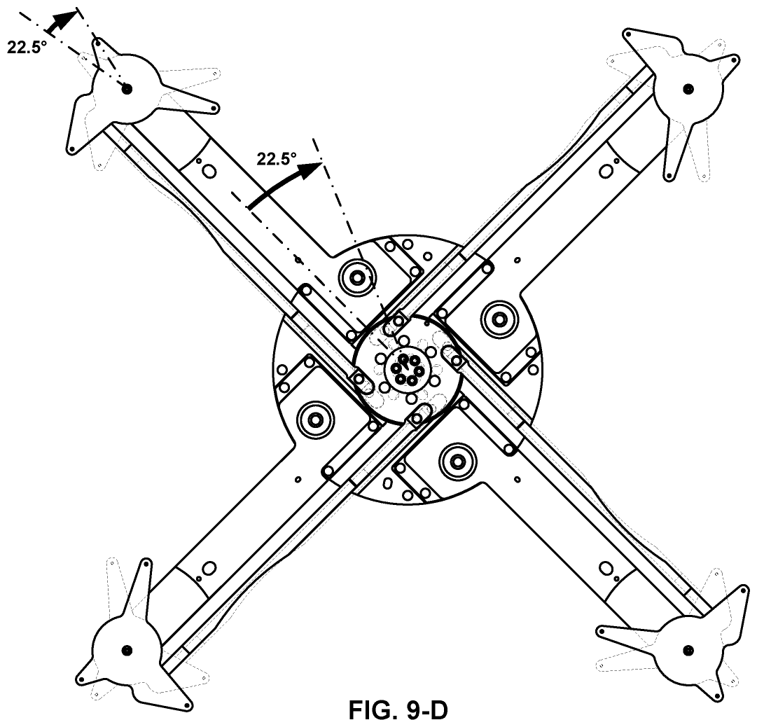

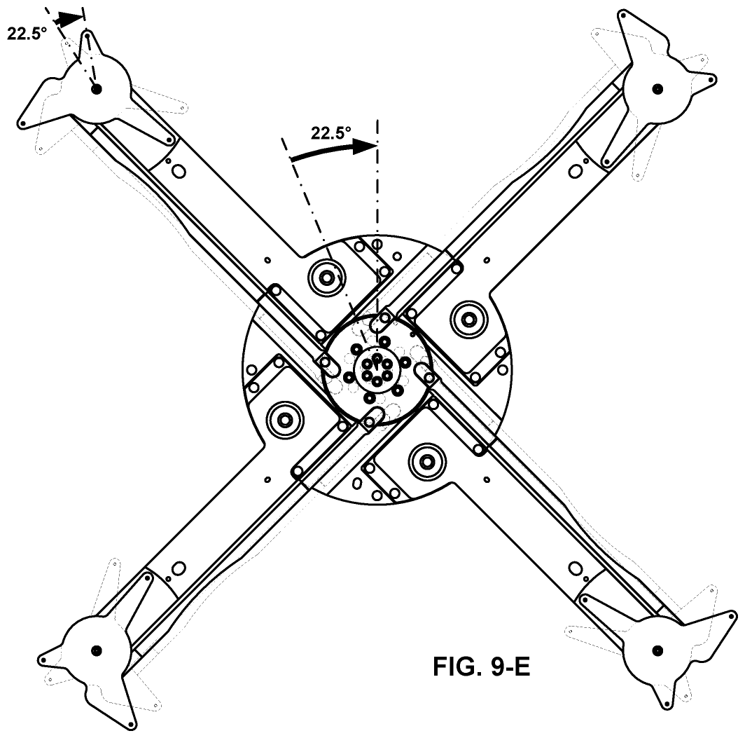

The offset region concept may also be employed in a manner that is “horizontal” instead of “vertical.” For example, FIG. 8 depicts such an implementation. As can be seen, the offset region 864 is offset from a nominal centerline (dash-dot-dot line in this Figure) of the tie-rod 846 by a distance D, which may be selected such that a proximal end 848 of an adjacent tie-rod 346 may be moved into the position shown without contacting the tie-rod 846 shown in FIG. 8 as having the offset region 864.

The rotational indexers with additional rotational axes disclosed herein may be particularly advantageous when used in certain types of semiconductor processing equipment. For example, in multi-station deposition or etch processing tools, there may be process non-uniformities in the wafers that are biased towards the center of the array of processing stations, e.g., towards the center axis 352.

If a conventional rotational indexer is used to move wafers from station to station in such a semiconductor processing tool, then the wafers may be subjected to such non-uniformities at each processing station and in the same manner, as the same edges of the wafers may be closest to the center axis 352 at every station. However, if a rotational indexer with additional rotational axes, as disclosed herein, is used to move wafers from station to station in such a semiconductor processing tool, then the wafers may be rotated from station to station such that a different edge or portion of the edge of the wafers may be closest to the center axis 352 at each station. This may help average out or mitigate the non-uniformities, thereby enhancing wafer processing quality.

FIGS. 9-A through 9-E depict the example rotational indexer of FIG. 3 through various states of actuation of the rotatable wafer supports located at the distal ends of the indexer arms. In this example, the first hub 330 is kept stationary and the second hub 332 is rotated in a clockwise manner (by 22.5° between each consecutive pair of Figures). The outlines of the positions of the moving parts in each previous Figure are depicted in dashed or broken lines. It will be understood that if the first hub 330 is rotated while the second hub 332 is held stationary, the wafer supports 338 will rotate in exactly the same manner relative to the indexer arms 340 at the same time that all of the indexer arms 340 rotate about the center axis 352. Thus, wafers supported by the wafer supports 338 may be simultaneously moved from station to station and rotated during each such movement so that the absolute angular orientation of the wafers relative to the word coordinate system remains the same.

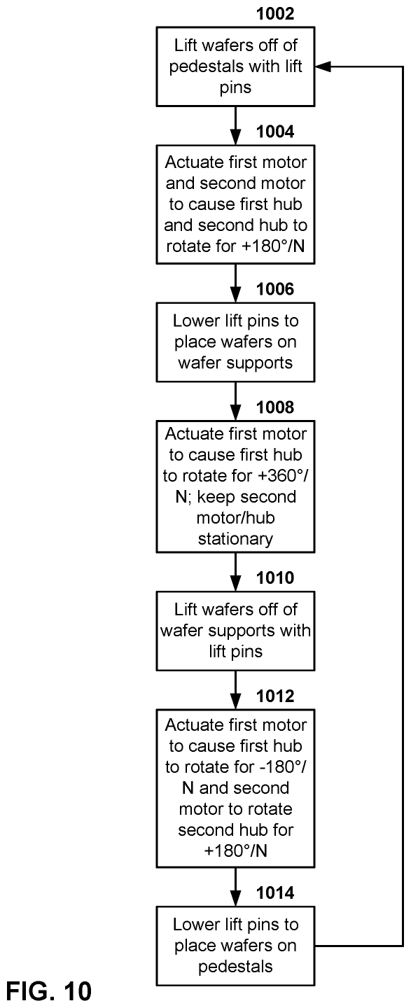

FIG. 10 depicts an example flow diagram for one technique for controlling a rotational indexer with additional rotational axes; the rotational indexer in question includes N equally-spaced indexer arms, where N is an integer greater than 1. The technique in FIG. 10 represents movements taken to sequentially advance a set of wafers from one station to the next in a semiconductor processing tool using such a rotational indexer. The technique may be repeated to perform further wafer advancement.

In block 1002, the wafers that are on each pedestal may be lifted off their respective pedestals, e.g., by activating a lift-pin system (in which pins located within each pedestal move upwards, or the pedestal moves downwards, in order to cause the wafer to be lifted off the pedestal upper surface to allow the wafer supports of the rotational indexer to be moved underneath the wafers.

In block 1004, the first motor and the second motor may be actuated so as to both rotate for +180°/N (or to cause the first hub to rotate for this amount); this assumes that each indexer arm is stowed midway between each station so as to not interfere with wafer processing operations when the rotational indexer is not in use. Such a rotation may cause the indexer arms and their wafer supports to move to locations where the wafer supports are underneath the wafers.

In block 1006, the lift pins may be lowered (or the rotational indexer elevated) to cause the wafers to be lifted off the lift pins by the wafer supports of the rotation indexer.

In block 1008, the first motor may be actuated so as to cause the first hub to rotate for 360°/N while the second motor is inactive or otherwise unactuated. As a result, the indexer arms may be rotated to move the wafers from their stations to the next adjacent stations while at the same time, the wafer supports may rotate relative to the indexer arms by the same amount in the same direction so as to maintain the wafers in the same absolute angular orientation.

In block 1010, the lift pins may be used to lift the wafers off of the wafer supports (or the rotational indexer may be lowered to cause the wafer to rest on the lift pins and be lifted off the wafer supports).

In block 1012, the first motor may be actuated to cause the first hub to rotate for 180°/N in the opposite direction as previous rotations while, at the same time, the second motor may be actuated to cause the second hub to rotate for 180°/N in the same direction as previous rotations. Thus, the relative rotational movement between the first and second hubs will be −360°/N, which may cause the wafer supports to rotate into the same angular position relative to indexer arms that they were in in between blocks 1002 and 1004, effectively resetting their positioning. At the same time, the indexer arms may be moved into their “stowed” positions midway between each pair of processing stations.

Once the indexer arms have cleared the processing stations, block 1014 may be performed to lower the wafers onto the pedestals for a further semiconductor processing operation. As noted above, this process may be repeated as desired to continue to advance the wafers through the array of processing stations.

It will be understood, as discussed earlier, that there are many ways to control the rotational indexer to perform wafer transfers between stations. The first hub and the second hub may be driven so as to move simultaneously, move sequentially, move at different rates and/or in different directions, and so forth. It will be appreciated that all such different combinations of actuating the motors for operating the rotational indexers described herein are considered to be within the scope of this application.

The above discussion has focused on implementations of a rotational indexer with additional rotational axes, as discussed in U.S. Pat. No. 10,109,517. Such rotational indexers, while allowing for wafers supported thereby to be not only rotated between processing stations but also be rotated relative to the indexer arms, may be limited in the rotational speed that the indexer arms may be rotated at. For example, wafers that are supported on the wafer supports of such rotational indexers may have a very low coefficient of friction, thereby significantly limiting the speed that the indexer arms may be rotated at before the centrifugal force applied to the wafer overcomes whatever friction forces exist between the wafer and the wafer support, thereby causing the wafer to slide off of the wafer support.

The present inventor realized that the indexer arm assemblies and actuation mechanism of a rotational indexer with additional rotational axes, as discussed earlier above, could be modified so as to provide a rotational indexer that is able to grip wafers from the edge, rather than only from beneath. By replacing the wafer supports discussed earlier with new wafer supports having a different geometry and revising how the controller that operates the rotational indexer controls the rotational indexer, it is possible to provide a rotational indexer that is able to move wafers between processing stations within a semiconductor processing chamber at rotational speeds that would be impossible to achieve without wafer slippage with a rotational indexer such as that discussed earlier with respect to FIG. 3.

The wafer supports of such a rotational indexer may be designed to not overlap with wafers that are supported on pedestals of a chamber when viewed along the axis of rotation of the rotational indexer while the indexer arms of the rotational indexer are positioned in between each pair of circumferentially adjacent wafers and the wafer supports are in a first rotational position relative to the indexer arms. At the same time, such wafer supports may, when rotated into a second rotational position relative to the indexer arms, each be able to partially support a pair of circumferentially adjacent wafers. This is perhaps best illustrated in FIGS. 11-1 through 11-5, which show a rotational indexer having such wafer supports in such rotational positions (as well as additional rotational positions in between such rotational positions).

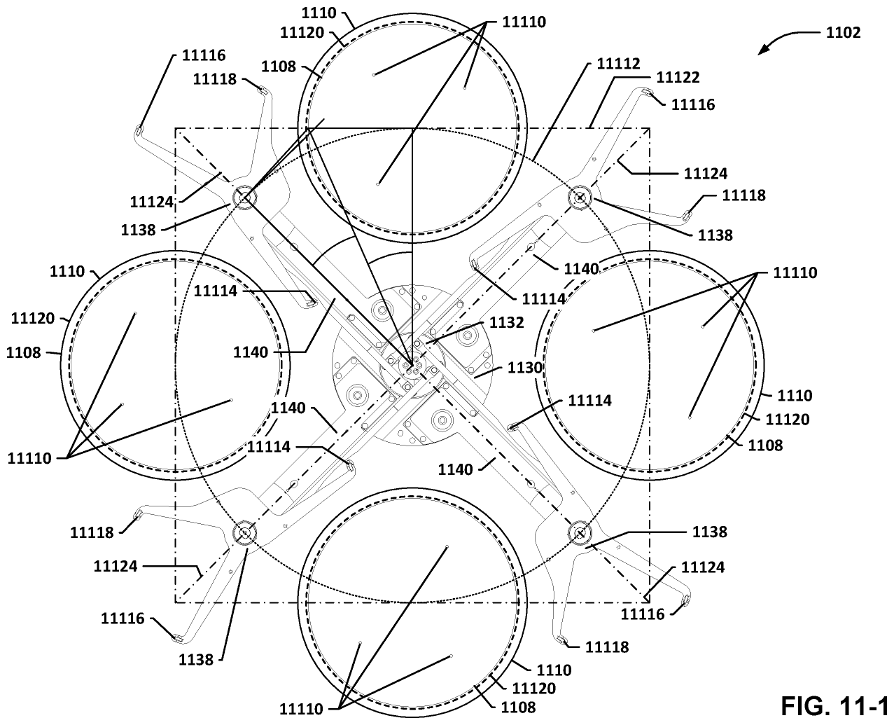

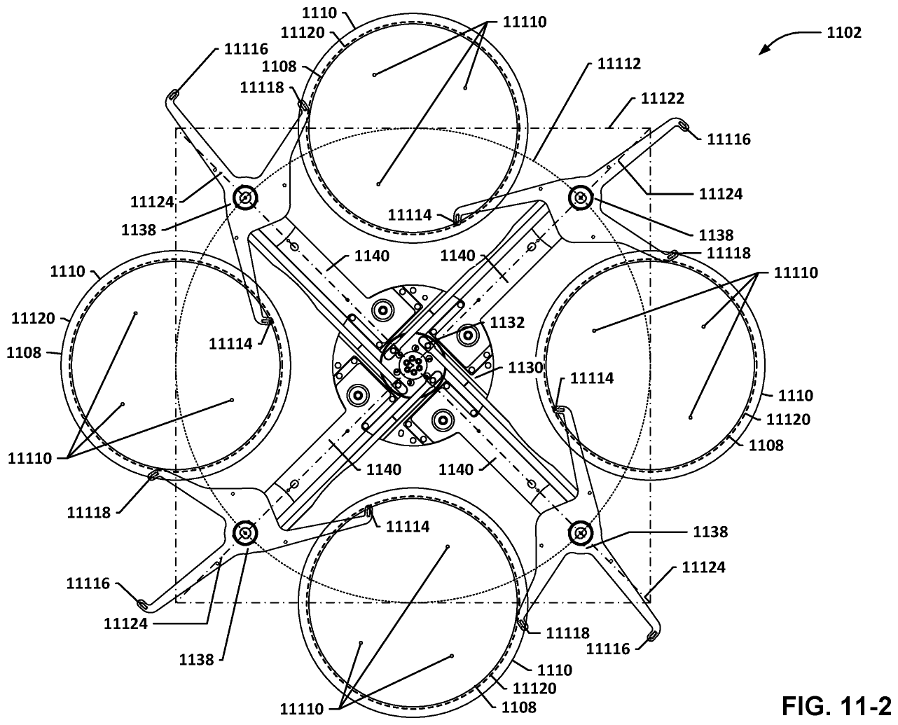

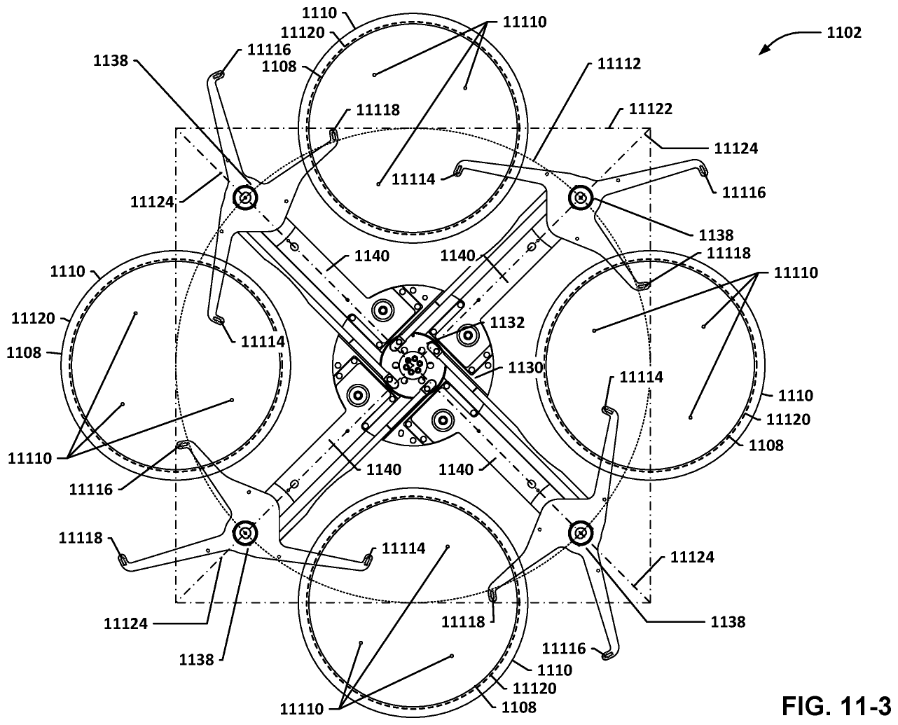

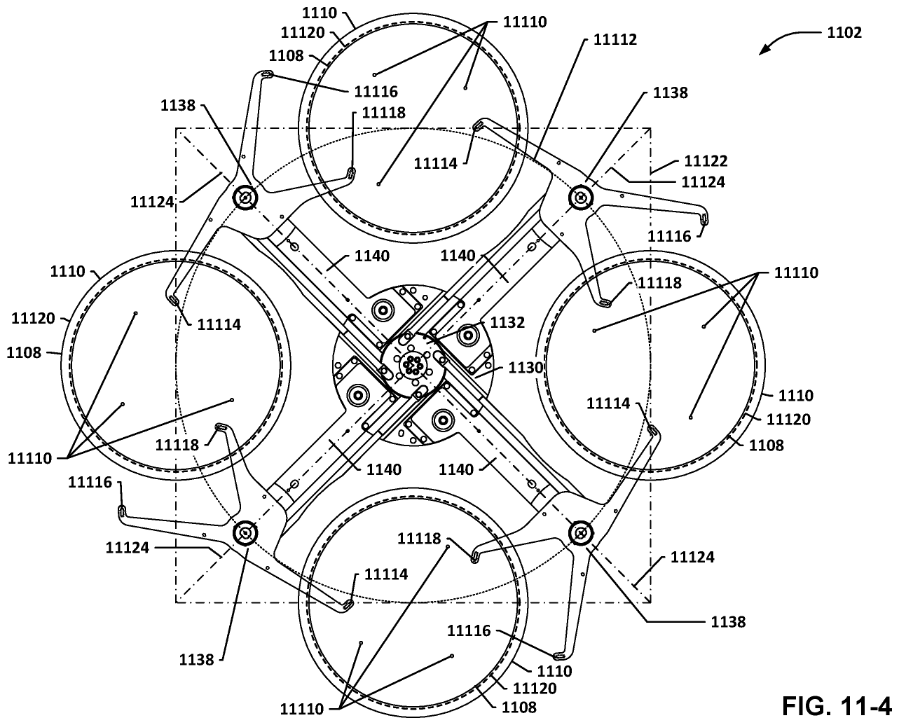

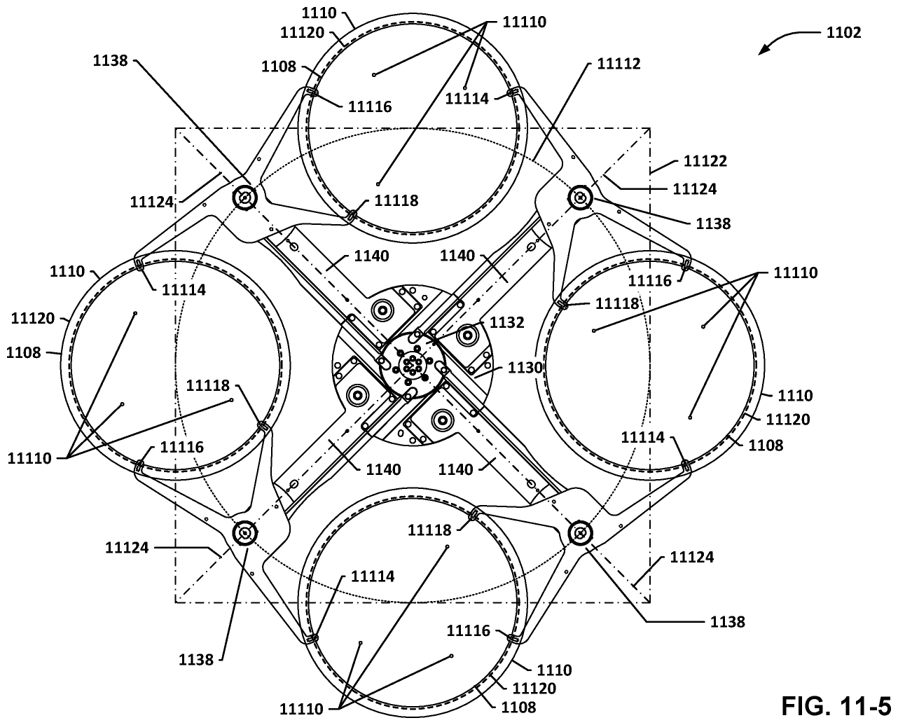

As can be seen in FIG. 11-1, a rotational indexer 1102 is shown. The rotational indexer 1102 includes a plurality of indexer arm assemblies that each include a wafer support 1138 and an indexer arm 1140 that extends radially outward from a first hub 1130. A proximal end of each indexer arm 1140 may be fixedly mounted with respect to the first hub 1130 while a distal end of each indexer arm 1140 may be rotatably connected with the corresponding wafer support 1138 such that the wafer support 1138 is able to rotate relative to the corresponding indexer arm 1140 and about a rotational axis located at the distal end of the corresponding indexer arm 1140. The first hub 1130 may be configured to be rotatable about a center axis of the rotational indexer 1102. Generally speaking, the first hub 1130 may be rotatable, relative to a base that supports the first hub 1130, about the center axis at least between a first angular position and a second angular position that are 360°/N apart, where N is the number of indexer arm assemblies extending outward from the first hub 1130. In the example of FIGS. 11-1 through 11-5, N=4, although it will be recognized that other rotational indexers embodying the concepts discussed with respect to FIGS. 11-1 through 11-5 and later Figures may have fewer or more indexer arm assemblies, e.g., 2, 3, 5, 6, etc. indexer arm assemblies. The base that is referenced above may, for example, be similar to the base 312 discussed earlier with respect to the rotational indexer 302.

The wafer supports 1138 may each have a plurality of corresponding wafer edge contact interfaces, such as a first wafer edge contact interface 11114, a second wafer edge contact interface 11116, and a third wafer edge contact interface 11118. In FIG. 11-1, the wafer supports 338 are in the first rotational position relative to the indexer arms 1140, while in FIG. 11-5, the wafer supports 1138 are in the second rotational position relative to the indexer arms 1140.

The rotational indexer 1102 may also include a second hub 1132 that may be caused to rotate relative to the first hub 1130 in order to cause linkages, e.g., tie-rods, to actuate and cause the wafer supports 1138 to rotate relative to the indexer arms 1140. The tie rods are not separately called out here, but it will be immediately apparent that the actuation mechanism that uses them may be similar to that discussed earlier with respect to, for example, the rotational indexer of FIG. 3 and may be operated in the same manner.

Circular reference regions 11120 may be defined between each circumferentially adjacent pair of indexer arm assemblies having indexer arms 1140. Such circular reference regions 11120 may each be centered on a common circular path 11112 that is centered on the center axis of the rotational indexer 1102 and may each have a common diameter D. In some implementations, the diameter D may be the same diameter as the diameter of the wafers that are to be handled by the rotational indexer 1102, e.g., 300 mm or 450 mm. The circular reference regions 11120 may, for example, be arranged in a circular array about the center axis of the rotational indexer 1102. As can be seen, when the wafer supports 1138 are in the first rotational position relative to the indexer arms 1140, e.g., as shown in FIG. 11-1, the wafer edge contact interfaces, e.g., the first wafer edge contact interfaces 11114, the second wafer edge contact interfaces 11116, and the third wafer edge contact interfaces 11118, are all located outside of the circular reference regions 11120. However, when the wafer supports 1138 are in the second rotational position relative to the indexer arms 1140, as shown in FIG. 11-5, the wafer edge contact interfaces, e.g., the first wafer edge contact interfaces 11114, the second wafer edge contact interfaces 11116, and the third wafer edge contact interfaces 11118, are all located at least partially within one of the circular reference regions 11120 (when viewed along the center axis of the rotational indexer 1102. The circular reference regions 11120, in this example, have diameters D that are equal to the diameters of semiconductor wafers 1108, which are shown resting on pedestals 1110 in FIGS. 11-1 through 11-5. The pedestals 1110 may be arranged in a circular array about the center axis of the rotational indexer. The rotational indexer 1102 is shown in FIGS. 11-1 through 11-5 as being in the same angular position during rotation of the wafer supports 1138 relative to the indexer arms 1140. This highlights a key difference between the rotational indexer of FIG. 3 and that of FIGS. 11-1 through 11-5—whereas some rotation of the rotational indexer 302 about its center axis needs to occur in order to transfer wafers that are on the pedestals 310 onto the wafer supports 338, the rotational indexer 1102 of FIGS. 11-1 through 11-5 does not necessarily need to undergo any rotational movement about its center axis in order to transfer the wafers 1108 that are on the pedestals 1110 onto the wafer supports 1138. For example, in order to load the wafers 1108 onto the wafer supports 1138, the wafers 1108 may first be lifted off of the pedestals 1110 by raising lift pins 11110 (three are provided at each pedestal 1110) such that the wafers 1108 are at a higher elevation than the outermost tips of the wafer supports 1138. The indexer arms 1140 and the first hub 1130 may then be held stationary while the wafer supports 1138 are rotated from the first rotational position (FIG. 11-1) to the second rotational position (FIG. 11-5). Once the wafer supports 1138 are in the second rotational position, as shown in FIG. 11-5, the lift pins 11110 may be retracted to lower the wafers 1108 onto the wafer edge contact interfaces, e.g., the first wafer edge contact interfaces 11114, the second wafer edge contact interfaces 11116, and the third wafer edge contact interfaces 11118, of the wafer supports 1138. Once the wafers 1108 are resting on the wafer edge contact interfaces and the lift pins 11110 have been retracted sufficiently into the pedestals 1110 that collision between the lift pins 11110 and the indexer arms 1140 cannot occur, the rotational indexer 1102 may be caused to rotate, e.g., by rotating the first hub 1130 and the second hub 1132 in tandem, to move the wafers 1108 between different pedestals 1110. After the wafers 1108 have been rotated so as to be above different pedestals 1110 by rotation of the rotational indexer 1102, the lift pins 11110 may be caused to move upwards, contact the undersides of the wafers 1108, and lift the wafers 1108 clear of the wafer supports 1138. The wafer supports 1138 may then be rotated from the second rotational positions relative to the indexer arms 1140 back to the first rotational positions relative to the indexer arms 1140. Once the wafer supports 1138 are rotated out of the way, the lift pins 11110 may be caused to retract into the pedestals 1110, thereby lowering the wafers 1108 onto the pedestals 1110.

One significant difference between the rotational indexer 1102 of FIGS. 11-1 through 11-5 and the rotational indexer 302 of FIG. 3 is that the wafer supports 1138 cannot be allowed to rotate (at least, not by any significant amount) relative to the indexer arms 1140 when supporting the wafers 1108 as shown in FIG. 11-5 since each wafer 1108 is cooperatively supported by two wafer supports 1138. If the wafer supports 1138 are caused to rotate relative to the indexer arms 1140 while supporting the wafers 1108 in this manner, at least one of the wafer edge contact interfaces, e.g., the first wafer edge contact interfaces 11114, the second wafer edge contact interfaces 11116, and the third wafer edge contact interfaces 11118, supporting the wafers 1108 will move to positions in which they no longer support the wafers 1108, thereby allowing the wafers 1108 to fall.

However, as will be discussed below, such an arrangement allows for more secure wafer transport between stations within the semiconductor processing chamber using the rotational indexer 1102.

As can be seen in FIGS. 11-1 through 11-5, axes 11124 may be defined that extend from the center axis of the rotational indexer 1102 and through the rotational axes of each wafer support 1138 located at the distal ends of the indexer arms 1140. In FIGS. 11-1 through 11-5, there are four axes 11124 that extend out from the center axis, each passing through the rotational axis of a different one of the wafer supports 1138. In implementations with more or fewer indexer arm assemblies, there may be corresponding larger or smaller axes 11124. A regular N-sided polygonal region 11122 may be defined that is centered on the center axis of the rotational indexer 1102 and has corners that each lie along a different one of the axes 11124. In FIGS. 11-1 through 11-5, the regular N-sided polygon 11122 is a square, although it will be understood that the regular N-sided polygonal region may be a triangle, pentagon, or other shape depending on the number N of indexer arm assemblies in a given rotational indexer. The regular N-sided polygonal region may also circumscribe the circular path 11112 on which the centers of the circular reference regions 11120 are located. In this example, the circular reference regions 11120 are also each concentric with, for example, the wafers 1108 and/or the pedestals 1110 (or the location on the pedestals 1110 that the wafers 1108 are to be centered on) when the rotational indexer 1102 is positioned with the indexer arms 1140 in between each pedestal 1110.

As can be seen from FIGS. 11-1 and 11-5, when the wafer supports 1138 are in the first rotational positions relative to the indexer arms 1140, the first wafer edge contact interfaces 11114 may all be located at least partially within (or entirely within) the regular N-sided polygonal region 11122 while the second wafer edge contact interfaces 11116 and the third wafer edge contact interfaces 11118 may be at least partially outside of (or entirely outside of) the regular N-sided polygonal region 11122. Similarly, when the wafer supports 1138 are in the second rotational positions relative to the indexer arms 1140, the first wafer edge contact interfaces 11114 and the second wafer edge contact interfaces 11116 may be at least partially outside of (or entirely outside of) the regular N-sided polygonal region 11122 while the the third wafer edge contact interfaces 11118 may be at least partially inside of (or entirely inside of) the regular N-sided polygonal region 11122. Such characteristics allow the wafer supports 1138 to adopt geometries that are able to engage the wafer edge contact interfaces with the edges of the wafers 1108 when in the second rotational position yet be clear of the wafers 1108 when the wafer supports 1138 are in the first rotational position. It will be appreciated and understood that when reference is made to a particular portion or feature of a component or assembly being “outside” or “within” a given region, it is intended that this be interpreted from a perspective that is along a direction perpendicular to the plane in which that region is defined. Thus, for example, determination of whether or not a portion or feature of the rotational indexer 1102 is “within” or “outside of” the regular N-sided polygonal region 11122 would be made based on a viewpoint that was along an axis that is parallel to the center axis of the rotational indexer.

By having at least the first wafer edge contact interfaces 11114 and the second wafer edge contact interfaces 11116 be at least partially outside of the N-sided polygonal region 11122 as shown in FIG. 11-5 (when the circular path 11112 also passes through the axes of the pedestals 1110 that the wafers 1108 are centered on or to be centered on), the first wafer edge contact interfaces 11114 and the second wafer edge contact interfaces 11116 will engage the wafers along the outermost half of each wafer, thereby generally providing each wafer with at least two points of contact with wafer supports 1138 along the outermost edge of the wafer 1108. This drives the distance between the first wafer edge contact interface 11114 and the second wafer edge contact interface 11116 that contacts a given wafer to generally be smaller than the diameter of the wafer 1108, thereby forming a gap that is smaller than the wafer 1108 diameter. The wafers 1108 are unable to fit through such gaps, and are thus prevented from slipping radially outward past the first wafer edge contact interfaces 11114 and the second wafer edge contact interfaces 11116 during rotation of the rotational indexer 1102.

Different types of wafer edge contact interfaces may be used in rotational indexers such as that shown in FIGS. 11-1 through 1105. FIGS. 12-1 through 13-2 depict two examples of wafer edge contact interfaces that may be used in a rotational indexer such as that shown in FIGS. 11-1 through 11-5.

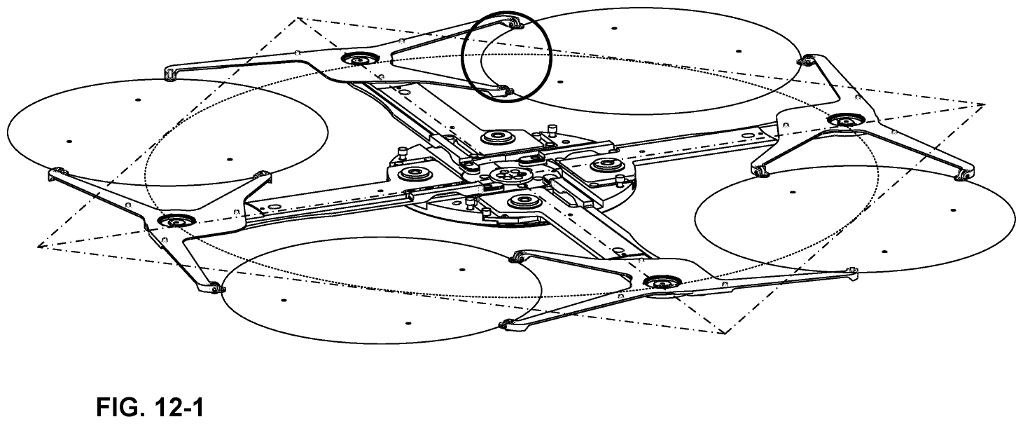

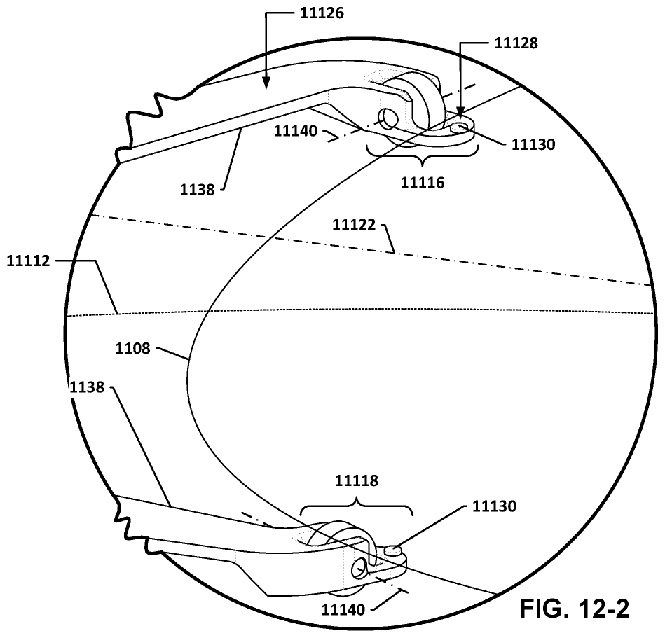

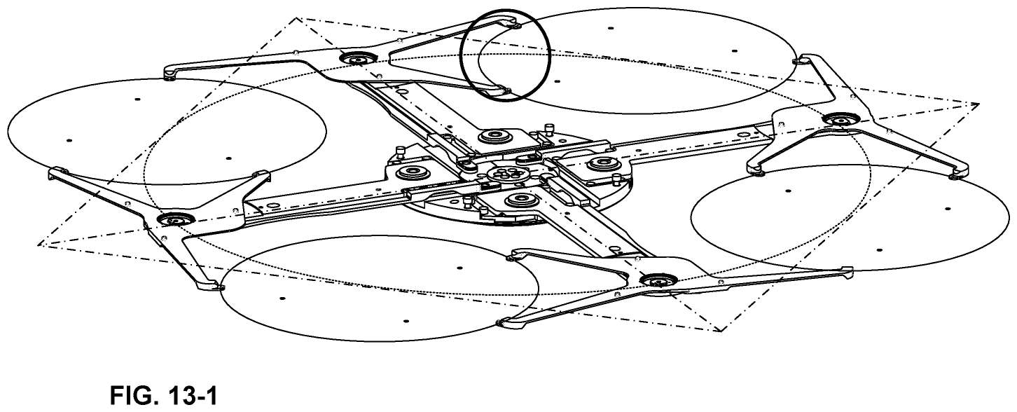

FIG. 12-1 depicts a perspective view of the rotational indexer 1102 of FIGS. 11-1 through 11-5. The individual components, axes, and circular or polygonal reference regions are not separately called out in FIG. 12-1, but reference may be made to FIGS. 11-1 through 11-5 in order to identify such features or elements. Also, the pedestals 1110 and the circular reference regions 11120 are not shown, and the wafers 1108 are represented by circular outlines representing where the edges of such wafer 1108 would be. Also visible are small circles within each wafer 1108 that represent locations where lift pins 11110 may contact the wafer 1108 during wafer-lift operations.

FIG. 12-2 depicts a detail view of the area enclosed in a heavy black circle in FIG. 12-1. As can be seen in FIG. 12-2, the second wafer edge contact interface 11116 and the third wafer edge contact interface 11118 are visible in more detail. The second wafer edge contact interface 11116 and the third wafer edge contact interface 11118 are each located at the end of cantilevered beam sections of the wafer support 1138. The second wafer edge contact interface 11116 and the third wafer edge contact interface 11118 may also each include a wafer support surface 11128 that is recessed downward from a top surface 11126 of the wafer support 1138. The wafer support surface 11128 may be sized and shaped so as to extend underneath the wafer 1108 when the wafer supports 1138 are in the second rotational position relative to the indexer arms 1140.

In effect, the wafer edge contact interfaces, such as the depicted second wafer edge contact interface 11116 and third wafer edge contact interface 11118, may include a stepped-down region that acts as a ledge that supports the underside of the wafer 1108 near the outer edge of the wafer 1108 or, alternatively, only contacts the bottom outer edge of the wafer 1108. The wafer support surfaces 11128 may, in some cases, each include a first protrusion 11130 that extends upwards from that wafer support surface 11128 and acts as a low- or minimum-contact area feature that is designed to contact the underside of the wafer 1108 only in a small area, thereby reducing or minimizing the potential for particulate generation arising from wafer 1108/wafer edge contact interface contact.

In implementations in which the circular reference regions 11120 are the same diameter as the diameters of the wafers 1108 (or larger in diameter than the diameters of the wafers 1108), the first protrusion 11130 of the first wafer edge contact interface 11114 of each wafer support 1138 may, when the wafer supports 1138 are in the second rotational positions relative to the indexer arm assemblies and the wafer supports 1138 are viewed along a direction parallel to the center axis of the rotational indexer 1102, be located within one of the circular reference regions 11120. At the same time, the corresponding first protrusions 11130 of the second wafer edge contact interface 11116 and the third wafer edge contact interface 11118 of that wafer support 1138 may, when the wafer supports 1138 are in the second rotational positions relative to the indexer arm assemblies and the wafer supports 1138 are viewed along a direction parallel to the center axis of the rotational indexer 1102, be located within a different one of the circular reference regions 11120 adjacent to the circular reference region 11120 in which the corresponding first protrusion 11130 of that first wafer edge contact interface 11114 is located.

Also visible in FIG. 12-2 are rollers 11138, which may be used to provide enhanced centering/seating of the wafers 1108 with respect to the wafer supports 1138 during wafer transfer operations. For example, each roller 11138 may be configured to be freely rotatable about a corresponding roller axis 11140 relative to the wafer support 1138 that supports that roller 11138.

In some implementations, the rollers 11138 may be positioned such that the roller axes 11140 are tangent to cylindrical reference surfaces that are defined by the circular reference regions 11120. For example, such cylindrical reference surfaces may have the same diameter as the circular reference regions 11120 and may have each have a center axis that is colinear with a different one of a plurality of reference axes that each pass through a center of a different one of the circular reference regions 11120 and are parallel to the center axis of the rotational indexer 1102. Put another way, the roller axes 11140 in such implementations may be parallel to a reference plane that is perpendicular to the center axis of the rotational indexer 1102 and may each be perpendicular to a normal of one of the reference axes.

In such implementations, if a wafer 1108 is slightly off-center with respect to the wafer supports 1138 when the wafer 1108 is being loaded onto the wafer support 1138, the rollers may engage with the edge of the wafer 1108 and then roll in order to cause the edge of the wafer 1108 to be guided radially inward into a more-centered position. Such an arrangement may avoid or reduce the potential for sliding contact between the wafer 1108 and the wafer edge contact interfaces.

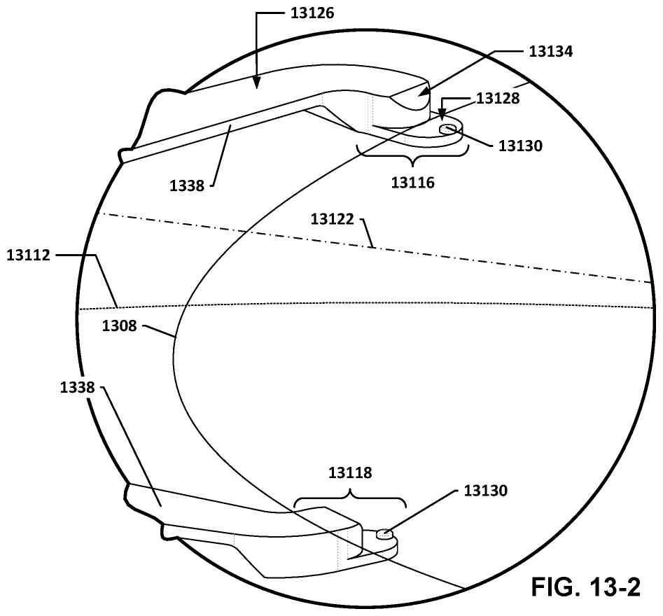

FIG. 13-1 depicts an alternate wafer edge contact interface design and is similar to FIG. 12-1. FIG. 13-2 depicts a detail view of the area enclosed in a heavy black circle in FIG. 13-1. As can be seen in FIG. 13-2, a second wafer edge contact interface 13116 and a third wafer edge contact interface 13118 are shown in more detail. The second wafer edge contact interface 13116 and the third wafer edge contact interface 13118 may each be located at the end of a cantilevered beam section of a wafer support 1338. The second wafer edge contact interface 13116 and the third wafer edge contact interface 13118 may also each include a wafer support surface 13128 that is recessed downward from a top surface 13126 of the wafer support 1338. The wafer support surface 13128 may be sized and shaped so as to extend underneath a wafer 1308 when the wafer supports 1338 are in a second rotational position relative to indexer arms (not shown) of the rotational indexer.

As with the wafer edge contact interfaces of FIG. 12-2, the wafer edge contact interfaces, such as the depicted second wafer edge contact interface 13116 and third wafer edge contact interface 13118, may include a stepped-down region that acts as a ledge that supports the underside of the wafer 1308 near the outer edge of the wafer 1308 or, alternatively, only contacts the bottom outer edge of the wafer 1308. The wafer support surfaces 13128 may, in some cases, also each include a first protrusion 13130 that extends upwards from that wafer support surface 13128 and acts as a low- or minimum-contact area feature that is designed to contact the underside of the wafer 1308 only in a small area, thereby reducing or minimizing the potential for particulate generation arising from wafer 1308/wafer edge contact interface contact.

Also visible in FIG. 12-2 are obliquely sloped surfaces 13134, which may be used to provide enhanced centering/seating of the wafers 1308 with respect to the wafer supports 1338 during wafer transfer operations. For example, each obliquely sloped surface 13134 may be configured so as to have a slope of 50°, 60°, 70°, or 80° relative to the center axis of the rotational indexer. Such obliquely sloped surfaces may extend between the wafer support surfaces 13128 and the top surfaces 13126 and may act to help guide the wafer 1308 towards a desired centered location as the wafer 1308 is lowered onto the second wafer edge contact interface 13116 and the third wafer edge contact interface 13118.

In some implementations, the obliquely sloped surfaces 13134 may be oriented such that a normal to that obliquely sloped surface is oriented towards one of a plurality of reference axes that is closest to that obliquely sloped surface. Each of the reference axes may pass through a center of a different one of the circular reference regions 13120 and may be parallel to the center axis of the rotational indexer.

As can be seen in the above examples, in some implementations, the first wafer edge contact interface 11114, the second wafer edge contact interface 11116, and the third wafer edge contact interface 11118 of each wafer support 1138 may all be at a distance from the rotational axis of that wafer support 1138 that is greater than half the diameters of the wafers 1108 that the wafer supports 1138 are configured to transport.

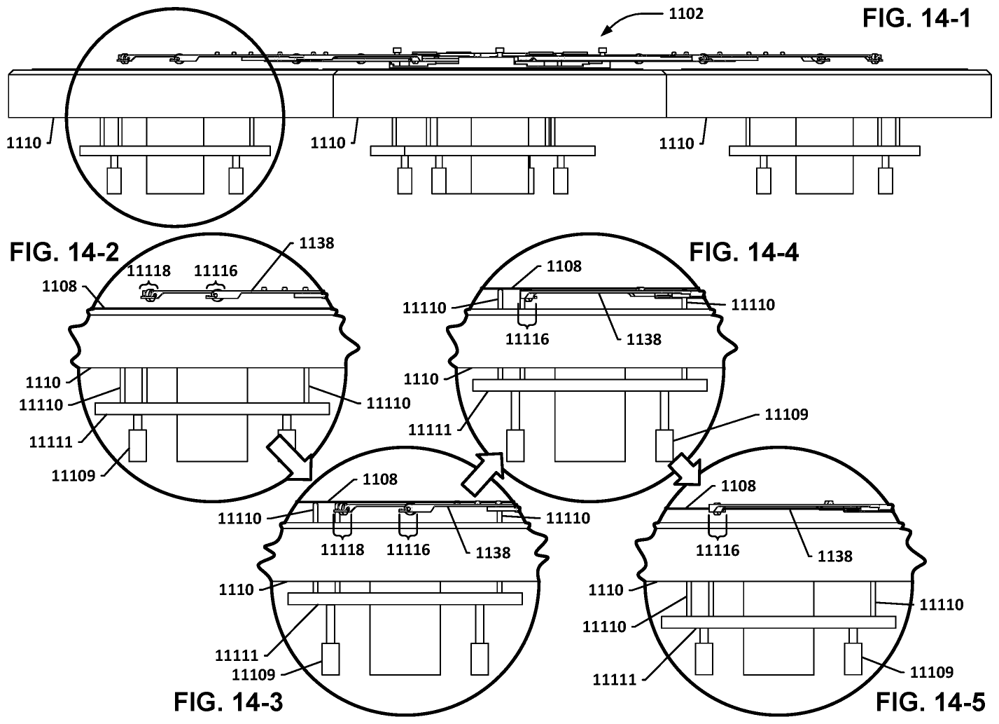

As discussed earlier, lift pins 11110 may be used to raise and lower the wafers 1108. FIG. 14-1 depicts a side view of the rotational indexer 1102 with pedestals 1110. FIGS. 14-2 through 14-5 depict detail views of the circled portion of FIG. 14-1 during various stages of lift pin operation.

As can be seen in FIG. 14-2, the wafer 1108 rests atop the pedestal 1110. Each set of lift pins 11110 for a pedestal 1110 is connected with a lift pin ring 11111 that is supported by a lift pin mechanism 11109. The lift pin mechanism 11109 may, as shown here, include one or more linear actuators that may be controlled so as to raise or lower the lift pin ring 11111 responsive to control signals received from a controller. Through-holes in the pedestal 1110 may allow the lift pins 11110 to be extended up through the pedestal 1110 when the lift pin mechanism 11109 is actuated. In FIG. 14, the rotational indexer 1102 is in the position indicated in FIG. 11-1. The viewpoint of FIG. 14-2 is from the bottom of FIG. 11-1 looking toward the top of FIG. 11-1, looking at the left-most pedestal 1110 and the wafer support 1138 at lower left.

In FIG. 14-3, the lift pin mechanism 11109 has been actuated so as raise the lift pins 11110 to lift the wafer 1108 clear of the pedestal 1110. The lift pins 11110 may be extended far enough through the pedestal so as to lift the wafer 1108 to an elevation that clears at least the wafer support surfaces 11128 of the wafer supports 1138. The wafer supports 1138 in FIG. 14-3 remain in the position shown in FIG. 14-2.

In FIG. 14-4, the lift pin mechanism 11109 remains in the same configuration as in FIG. 14-3, but the wafer supports 1138 have now been rotated into the positions shown in FIG. 11-5, thereby placing portions of the wafer support surfaces 11128 underneath the wafers 1108.

Finally, in FIG. 14-5, the lift pin mechanism 11109 has been actuated to retract the lift pins 11110 into the pedestal 1110, thereby lowering the wafer 1108 onto the wafer support 1138. It will be understood that the rotational indexer 1102 remains in the first angular position relative to the base (not shown) in FIGS. 14-1 through 14-5.

It will be understood that the lift pins 11110, while shown as being moved between only two different positions in FIGS. 14-2 through 14-5, may, in some cases, be moved between at least three different states. For example, the lift pins 11110 may be in a first state when the wafer 1108 is resting on the pedestal 1110, e.g., a state in which the lift pins 11110 are fully retracted into the pedestal 1110. The lift pins 11110 may be in a second state when in one or both of the configurations shown in FIGS. 14-3 and 14-4, e.g., a state that is higher than the first state. Finally, the lift pins 11110 may be in a third state when in the position shown in FIG. 14-5, e.g., at an elevation lower than in the second state. In some cases, as shown in FIGS. 14-2 through 14-5, the lift pins 11110 may be at the same elevation in the first state and the third state, although this is not necessarily required.

Once the wafers 1108 are loaded onto the wafer supports 1138 of the rotational indexer 1102, the rotational indexer may be caused to rotate about its center axis, e.g., responsive to a control signal from the controller, thereby moving the wafers 1108 from their respective processing stations within the semiconductor processing chamber that houses the rotational indexer 1102 to other such processing stations. Once the wafers are in position at their new processing stations, the steps shown in FIGS. 14-2 through 14-5 may be performed in reverse to transfer the wafers 1108 off of the wafer supports 1138 and onto the pedestals 1110 at those processing stations.

As discussed earlier, the rotational indexer 1102 differs from the rotational indexer 302 in that the rotational indexer 302 may be used to not only transfer wafers 308 between stations/pedestals, but may also be used to rotate the wafers 308 about their center axes relative to the indexer arms, thereby allowing the rotational orientation of the wafers relative to the center of the rotational indexer to be changed as well. In contrast, the rotational indexer 1102 is able to transfer the wafers 1108 between stations/pedestals at higher rotational speeds without risking the wafers 1108 sliding off of the wafer supports, but is unable to rotate the wafers 1108 about their center axes relative to the indexer arms.

However, with some further modification, the rotational indexer 1102 may also be able to rotate the wafers 1108 about their center axes relative to the indexer arms. FIGS. 15-1 through 15-9 depict such a variant. For the sake of brevity, the elements of the embodiment of FIGS. 15-1 through 15-9 that are identical to corresponding elements in the embodiment of FIGS. 11-1 through 11-5 are called out with callouts in FIGS. 15-1 through 15-9 having the same last two digits as their counterparts in FIGS. 11-1 through 11-5. The discussion of those elements with respect to FIGS. 11-1 through 11-5 is equally applicable to the embodiment of FIGS. 15-1 through 15-9, except as noted below, and the reader is referred to such earlier discussion for discussion of similar elements in FIGS. 15-1 through 15-9.

The only real structural difference between the rotational indexer 1502 and the rotational indexer 1102 is in the wafer supports 1538 and 1138. The wafer supports 1138, for example, have a central portion with generally straight, cantilevered beams radiating outward therefrom, with each beam terminating in a different wafer edge contact interface. The geometry of the wafer supports 1138 allows for the wafer supports 1138, when in the first rotational position relative to the indexer arms, to be completely outside of the cylindrical reference regions discussed earlier (defined by the circular reference regions 11120) but to also have the wafer edge contact interfaces thereof at least partially within such circular reference regions 11120 when the wafer supports 1138 are in the second rotational positions relative to the indexer arms.

In contrast, the wafer supports 1538 may, while having wafer edge contact interfaces that are arranged in the same manner as the wafer edge contact interfaces in the wafer supports 1138, have a central portion that has cantilevered beams extending therefrom, and to the wafer edge contact interfaces, that have, in some cases, more complex shapes.

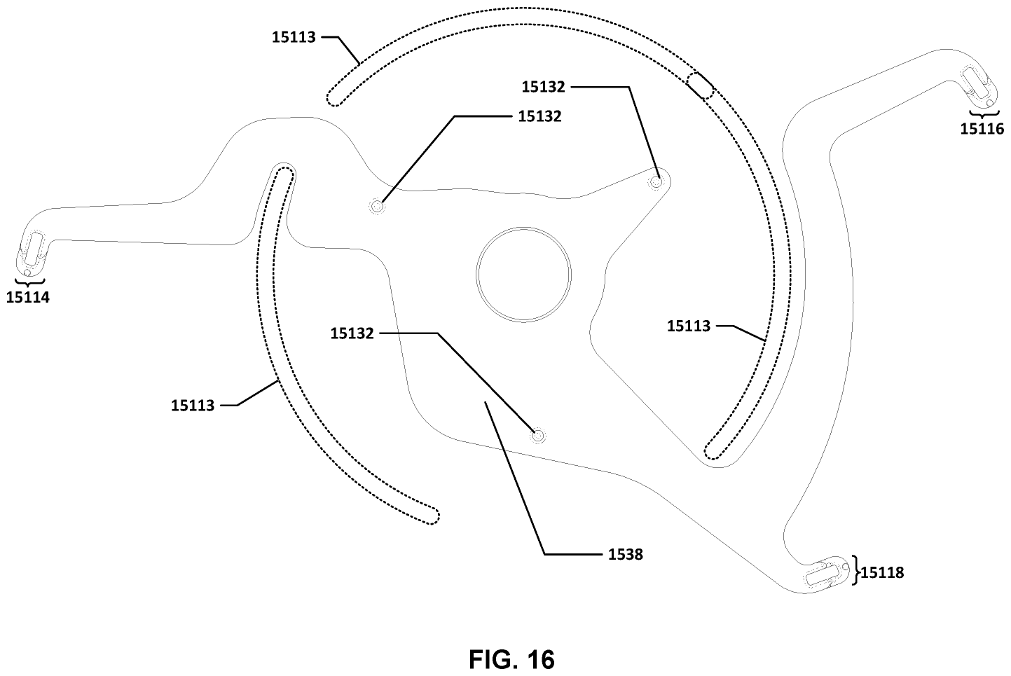

FIG. 16 depicts a top view of one of the wafer supports 1538 that illustrates some of the features of such wafer supports 1538. For example, the wafer support 1538 may be designed such that the cantilevered beam portions that extend radially outward from the center portion of the wafer support 1538 do not have any material within a plurality of arcuate regions 15113 that are all centered on the axis of rotation of the wafer support 1538. These arcuate regions 15113 may each have a centerline that is at the same distance from the center of rotation of the wafer support 1538 as the centers of the lift pins 15110 are from the location on the pedestals 1510 that the wafers 1508 are to be centered on. The arcuate regions 15113 represent regions, relative to the wafer support 1538, in which the wafer support 1538 has no material. By having such material-free regions, the wafer support 1538 may be able to rotate to either extreme of its rotational range relative to the indexer arms while the rotational indexer is in the second angular position (with the center of rotation of the wafer support 1538 centered over the location on the pedestal 1510 on which the wafer 1508 is to be centered) without colliding with an extended lift pin 15110. This is perhaps best illustrated in FIGS. 15-6 through 15-9.

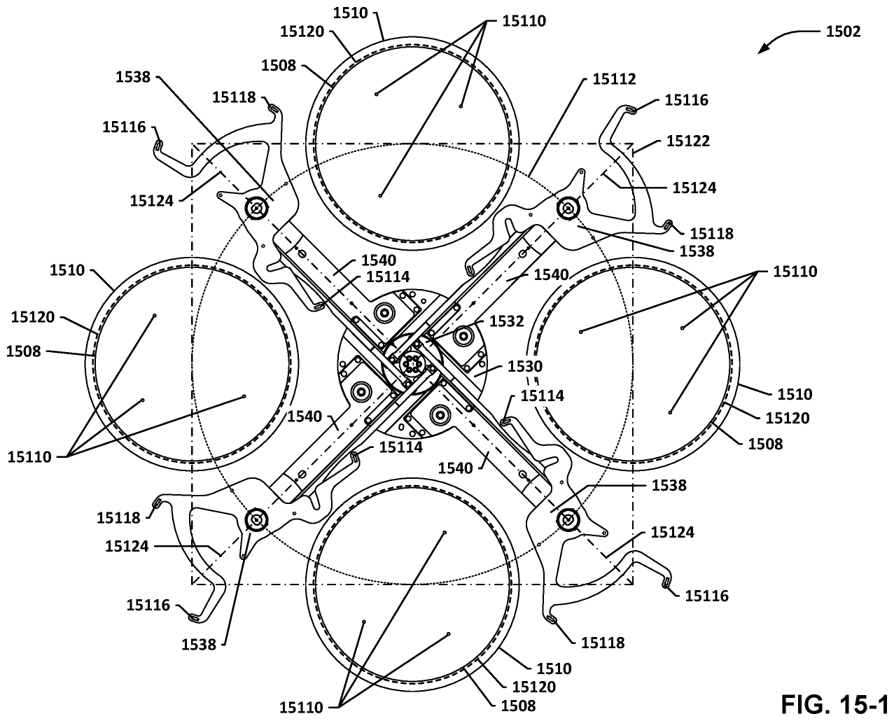

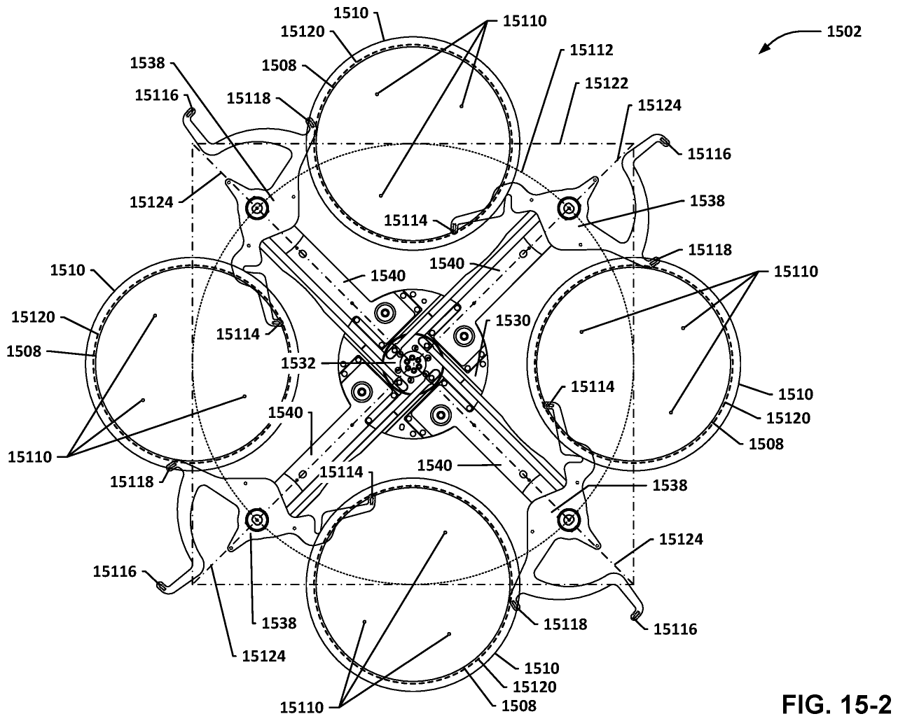

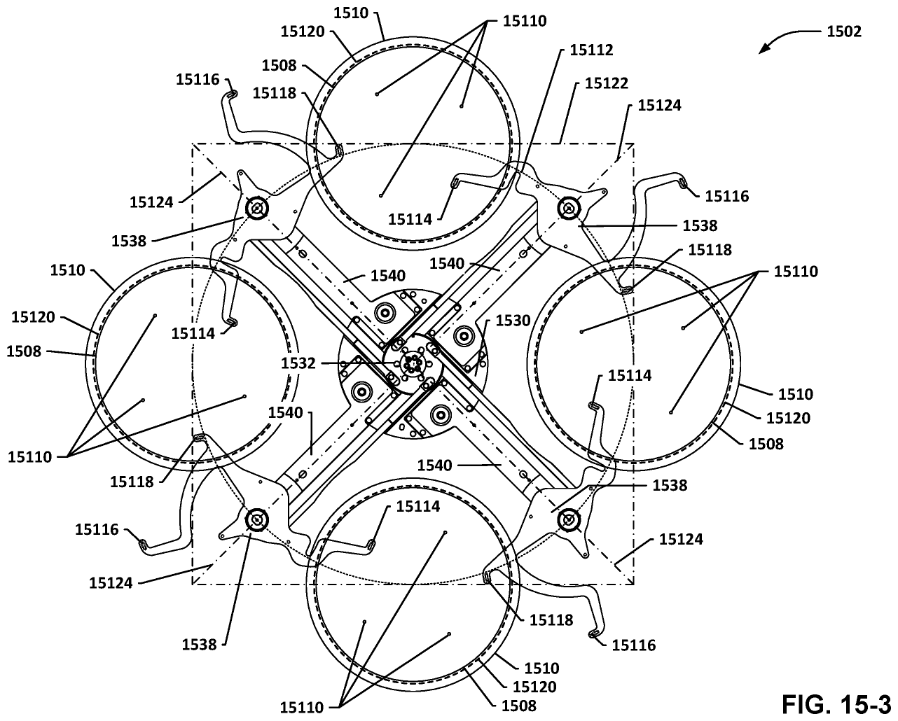

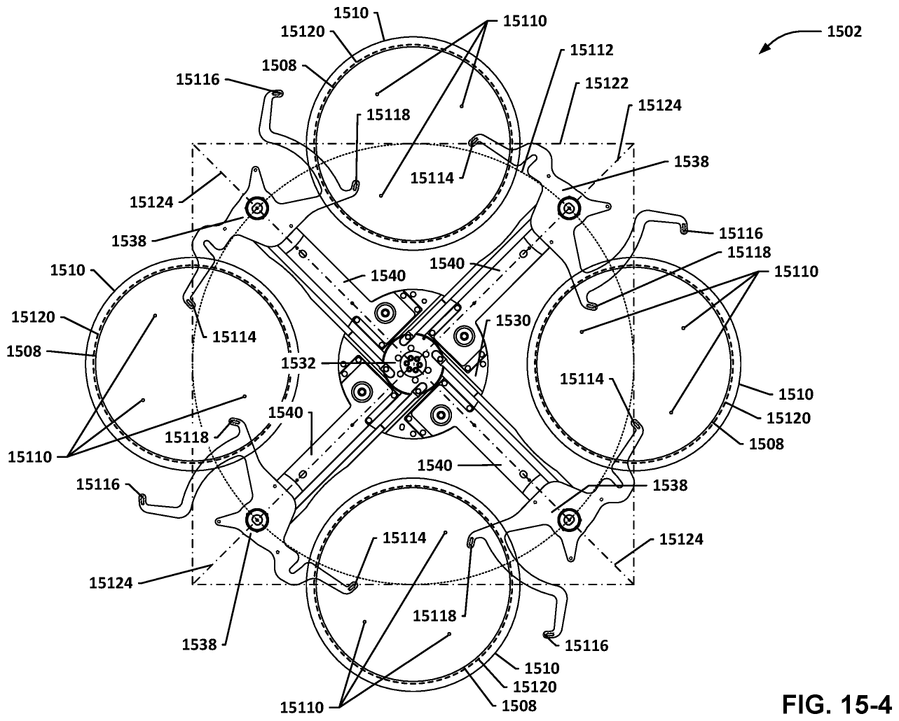

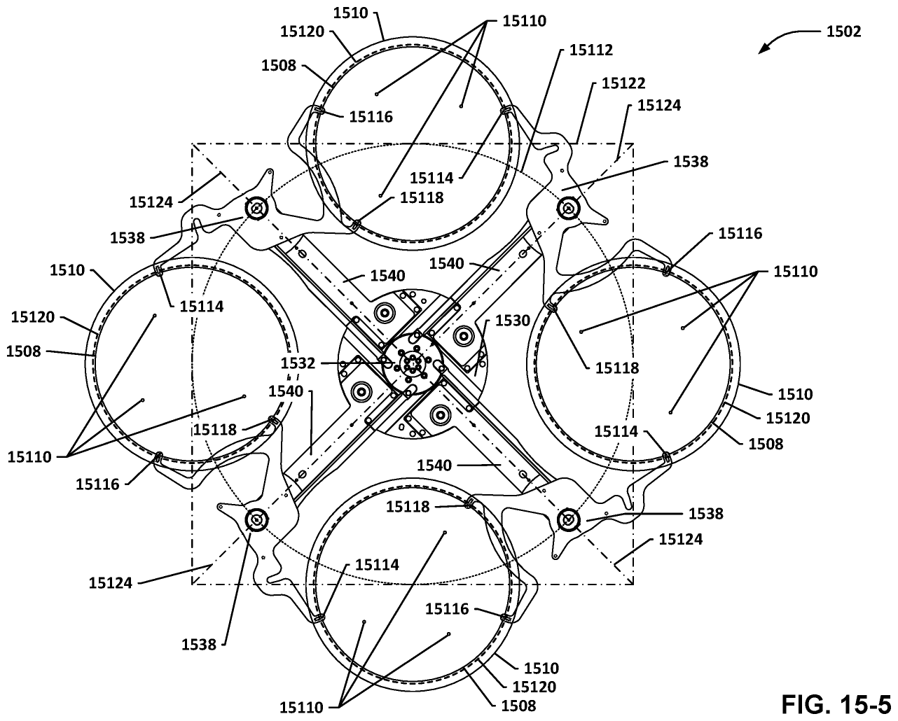

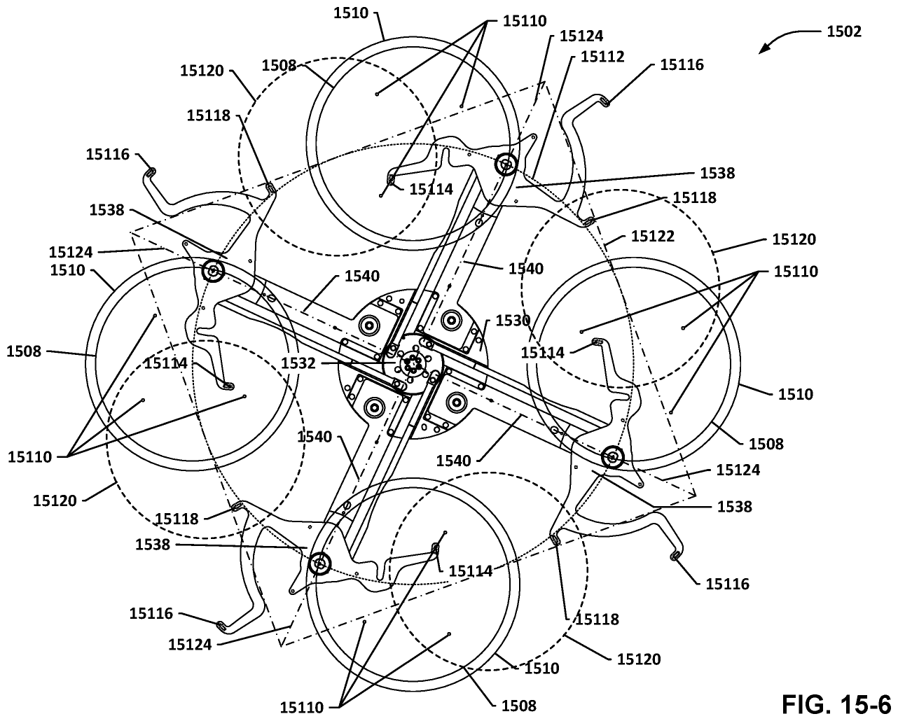

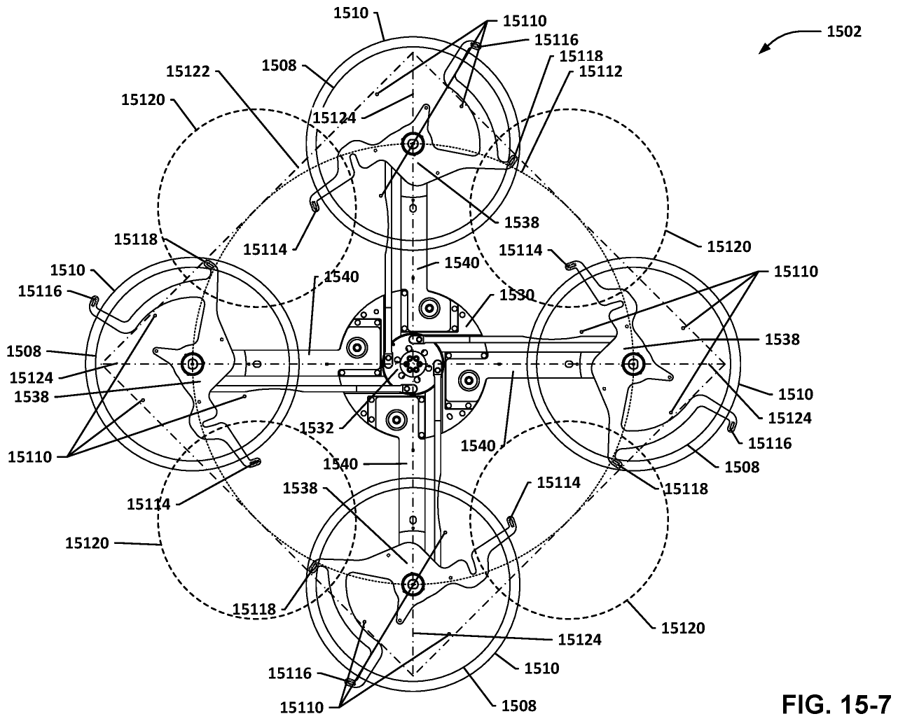

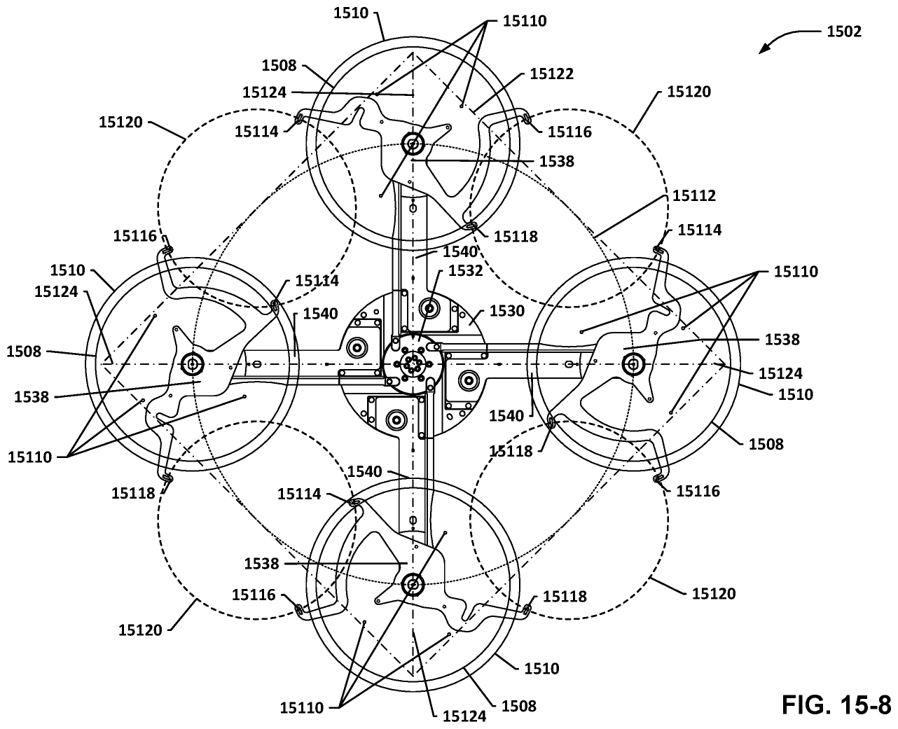

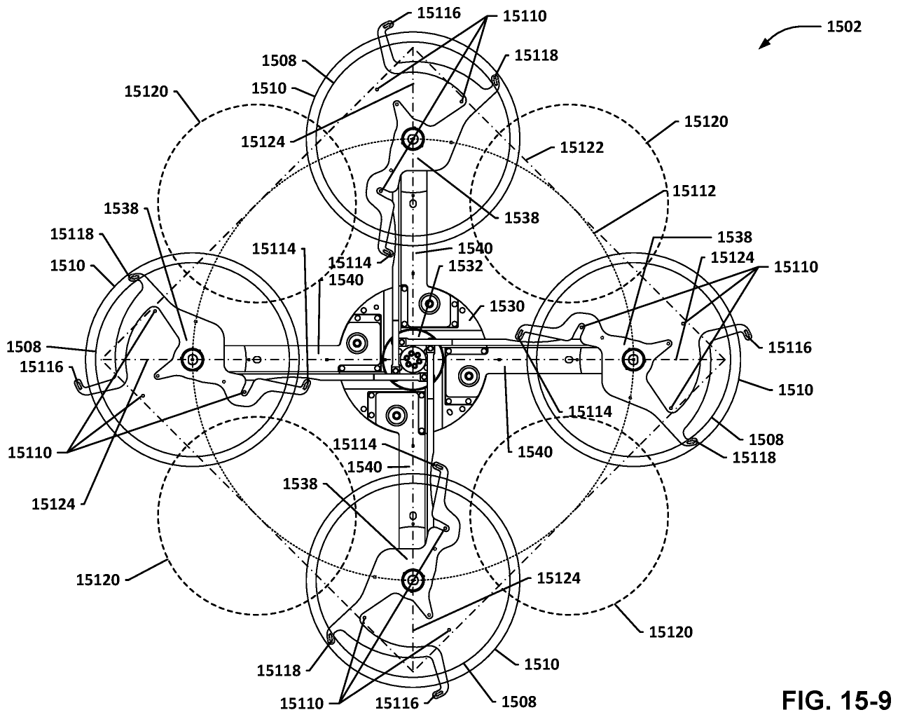

If it is desired to rotate the wafers 1508 relative to the indexer arms 1540, the lift pins 15110 may first be caused, through actuation of a lift pin mechanism similar to the lift pin mechanism 1109, to be raised to a fourth state, thereby lifting the wafers 1508 off of the pedestals 1510 and above the elevation of the wafer support surfaces of the wafer edge contact interfaces of the wafer supports 1538. The rotational indexer 1502 may then be caused—while the lift pins are in the fourth state (or one or more other elevated state)—to transition to the second angular position relative to a base of the rotational indexer 1502 in order to position the wafer supports 1538 under the wafers 1508. For example, the wafer supports 1538 may be caused to transition partway from the first rotational position to the second rotational position, as shown in FIGS. 15-1 through 15-3, at which point the first hub 1530 may be caused to rotate as well, thereby causing the indexer arms 1540 to rotate about the center axis of the rotational indexer 1502. The rotation of the first hub 1530 is shown in FIGS. 15-6 and 15-7. Once the rotational indexer 1502 is in the second angular position, the wafer supports 1538 may then be caused to rotate to either the first rotational position (FIG. 15-8) or the second rotational position (FIG. 15-9) relative to the indexer arms 1540, depending on whether the wafers 1508 are to be rotated clockwise or counterclockwise after being placed on the wafer supports 1538, while the lift pins 15110 are in the fourth state. Once the wafer supports are in either the first rotational position or the second rotational position relative to the indexer arms, the lift pins may 15110 be retracted to be in a fifth state, e.g., into the pedestals 15. The fifth state may generally be lower than the fourth state, although it is not necessarily the case that the fifth state will require that the lift pins 15110 be withdrawn completely into the pedestal 1510 (although this is certainly possible). By withdrawing the lift pins 15110 into the fifth state, the wafers 1508 may be caused to descend onto the wafer supports 1538 and come to rest thereon. Thus, when the wafer supports 1538 are caused to rotate relative to the indexer arms 1540, the wafers 1508 may rotate with them.

The top surfaces of the wafer supports 1538 may, in some instances, be equipped with second protrusions 15132 that may, for example, be arranged in triangular patterns on the top surfaces. The second protrusions 15132 for a given wafer support 1538 may, for example, be positioned so as to contact the underside of the wafer 1508 placed upon that wafer support and to stably support it while preventing the majority of the wafer support 1538 from contacting the underside of the wafer 1508.

It will be understood that the arcuate regions 15113, while shown as having the same radii, may also be at different radii in some implementations. In some cases, at least one of the arcuate regions 15113 may be separated from circumferentially adjoining arcuate regions 15113 by circumferential gaps, e.g., such as the two gaps visible between the arcuate regions 15113 in FIG. 16. In some implementations, there may be only two circumferential gaps between arcuate regions 15113 for a given wafer support 1538, as shown in FIG. 16. These circumferential gaps provide zones in which there may be material of the wafer support 1538 that connects the interior portion of the wafer support with the outer portions of the wafer support, e.g., that include the distal ends of the wafer support 1538. In some instances, one of the cantilever beam sections 15142 of the wafer support 1538, e.g., such as the one supporting the first wafer edge contact interface 15114, may extend generally radially outward along a path from the center portion of the wafer support 1538. The path may have a jog 15144 in it that causes the beam section to shift from extending in a generally radial manner to extending in a circumferential manner before again extending in a radial manner and then extending in the opposing circumferential direction before returning to extending out in a generally radial manner. The jog may provide a U-shaped feature that may act to provide clearance for a lift pin 15110 in some rotational positions.

Similarly, the beam sections 15142 for the second wafer edge contact interface 15116 and the third wafer edge contact interface 15118 may, in some implementations, both share a common structure for part of their lengths, e.g., as shown in FIG. 16. The beam section 15142 for the third wafer edge contact interface 15118, for example, may similarly extend radially outward from the center portion of the wafer support 1538, but may not, for example, have a jog in it. The beam section 15142 for the second wafer edge contact interface 15116 may, for example, include part of the beam section 15142 for the third wafer edge contact interface 15118 but may then extend out from that portion along a circumferential path for some distance, e.g., 30° or more, and may then extend out radially again before reaching the second wafer edge contact interface 15116.

The above-discussed examples have featured indexers with rotatable wafer supports that are designed to each carry a portion of a semiconductor wafer via edge contact, e.g., each semiconductor wafer is supported at its edges by two wafer supports working in cooperation. Such an approach provides a two-fold benefit. First, as discussed earlier, the rotational speed of the indexer may be higher for edge-supported semiconductor wafers since the wafer edge contact interfaces used may prevent the semiconductor wafers from slipping off due to centrifugal force during rotation of the indexer at higher speeds. This decreases the amount of time needed to transport semiconductor wafers between pedestals, thereby increasing the number of semiconductor wafers that may be processed in a given unit time (and thus increasing the throughput of the tool having such an indexer). Second, contact between the semiconductor wafers and the indexer is limited to the edges of the semiconductor wafers. Contact between the back sides of the semiconductor wafers and the indexer is avoided, thereby reducing the potential for abrasion of the interior regions of the backsides of the semiconductor wafers by the wafer supports, which may potentially damage patterned features or deposited films in such regions.

An alternative approach that is somewhat less complicated than the above examples may provide similar benefits with respect to preventing radial slippage of the semiconductor wafers but without the added benefit of avoiding contact between the semiconductor wafers and the interior regions of the backsides of the semiconductor wafers.

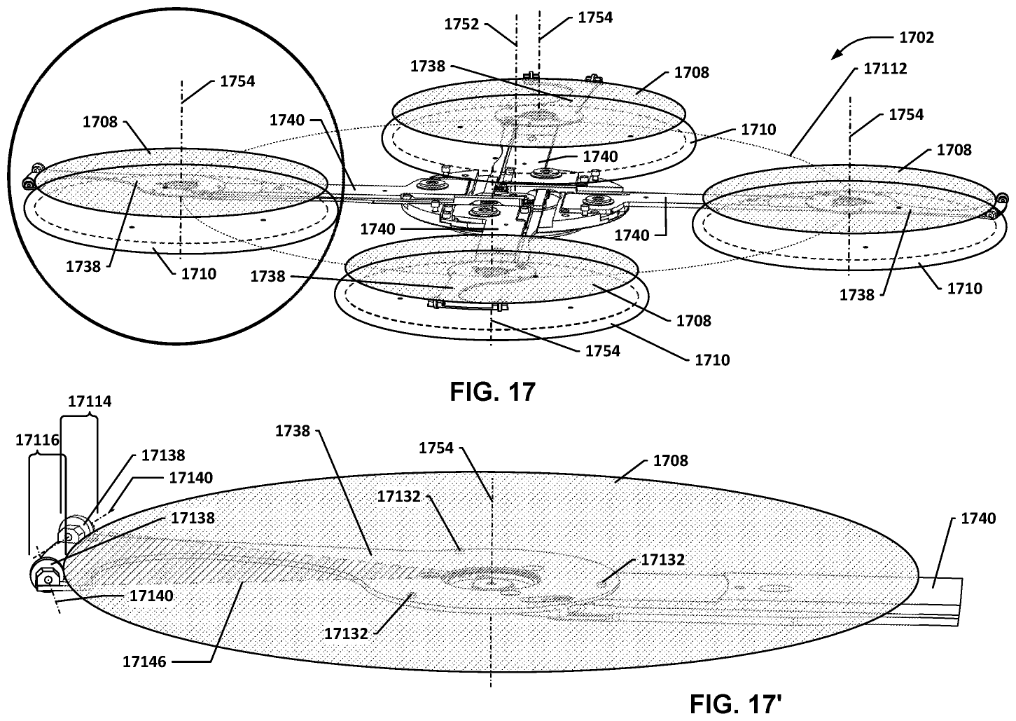

FIG. 17 depicts a perspective view of a rotational indexer featuring rotatable wafer supports that are each configured to separately support, and prevent radial slippage of, a semiconductor wafer during indexing operations. FIG. 17′ depicts a detail view of the portion of FIG. 17 inside the circled region.

FIG. 17 depicts a rotational indexer 1702 with a first hub fixedly connected with a plurality of indexer arm assemblies. Each indexer arm assembly may include a corresponding indexer arm 1740 with a proximal end of the indexer arm 1740 fixedly connected with the first hub and a distal end that supports a wafer support 1738 that is rotatable about a corresponding rotational axis 1754 that is located at the distal end of the indexer arm 1740. Each wafer support 1738 may be rotatable between at least a first rotational position relative to the indexer arms 1740 and a second rotational position relative to the indexer arms 1740. The wafer supports 1738 may be placed in the second rotational position, as shown in FIG. 17, when used to support the wafers 1708 during rotation of the indexer arms 1740 about the center axis 1752.

The first hub, in FIG. 17, may be rotated about the center axis 1752 relative to the base and between at least two angular positions that are 360°/N apart. The first hub is shown rotated in FIG. 17 such that the wafer supports 1738 located at the distal ends of the indexer arms 1740 are each positioned above a pedestal 1710 (only the top surfaces of the pedestals 1710 are shown). The wafer supports 1738 each support a wafer 1708. In this respect, the indexer 1702 is very similar to the indexer 302 discussed earlier herein. Each wafer support 1738 is configured to be able to rotate about a corresponding rotational axis 1754 (positioned at a distal end of the corresponding indexer arm 1740) relative to the indexer arms 1740. The rotational indexer 1702 may include an actuation mechanism similar to those described with respect to earlier examples that may be used to cause the wafer supports 1738 to rotate relative to the indexer arms 1740 and/or to cause the indexer arms 1740 (and wafer supports 1738 supported thereby) to rotate about a center axis 1752, thereby moving the wafers 1708 along a circular path 17112. The rotational indexer 1702 may have a base (not shown) containing motors for actuating the rotational indexer 1702, for example, that is similar to the bases discussed herein with respect to earlier examples.

As can be seen more clearly in FIG. 17′, each wafer support 1738 may be configured to support a wafer 1708 from below when the wafer 1708 is placed on that wafer support 1738. For example, the wafer supports 1738 may each have a plurality of protrusions 17132, e.g., three protrusions 17132, that extend from an upper surface of the wafer support 1738 and may serve as contact points between the wafer support 1738 and the wafer 1708 supported thereby. It will be understood that fewer or greater than three such points of contact may be used to support the wafers, but three discrete points of contact will support the wafer 1708 in a stable manner with minimal contact between the wafer 1708 and the wafer support 1738.

The wafer supports 1738, however, differ from the wafer supports 338 in that each wafer support 1738 includes a portion that extends out beyond the edge of the wafer 1708 when the wafer is placed on the wafer support 1738 with the wafer 1708 centered on the rotational axis 1754 of the wafer support 1738. This portion of the wafer support 1738 is located more than one half of the diameter of the wafer 1708 from the rotational axis 1754 and may include one or more wafer edge contact interfaces, such as a first wafer edge contact interface 17114 and a second wafer edge contact interface 17116. The wafer edge contact interfaces may protrude up from the wafer support 1738 sufficiently far enough that a surface of each wafer edge contact interface extends past the edge of the wafer 1708 when the wafer 1708 is supported by the wafer support 1738. This surface may be positioned such that it is, for example, at approximately one half of the diameter of the wafer 1708 from the rotational axis 1754 of the wafer support 1738 (ideally, the surface is exactly one half of the diameter of the wafer 1708, it may also be slightly more or less, depending on the tolerance that is acceptable with regard to how centered the wafer 1708 is on the rotational axis 1754. When the wafer 1708 is supported by the wafer support 1738 and the edge of the wafer 1708 is in contact with the one or more wafer edge contact interfaces, the center of the wafer 1708 will generally be centered on the rotational axis 1754. When the wafer supports 1738 are in the position shown, with the one or more wafer edge contact interfaces positioned outboard of the wafer 1708 with respect to the center axis 1752 of the rotational indexer 1702, the wafer edge contact interface(s) may act as positive stops that limit radial outward movement of the wafer 1708, e.g., such as the wafer sliding radially outward off of the wafer support 1738 when the indexer arms 1740 are rotated about the center axis 1752 at a speed that causes the centrifugal force to overcome the friction forces between the wafer support 1738 and the wafer 1708.

The wafer edge contact interfaces, e.g., the first wafer edge contact interface 17114 and the second wafer edge contact interface 17116, may, in some instances, each include a roller 17138 that is configured to rotate about a corresponding roller axis 17140. In some implementations, the roller axes 17140 may be parallel to a reference plane that is perpendicular to the center axis 1752. If the wafers 1708 are positioned such that they are off-center from the rotational axes 1754 in a radially outward direction, the rollers 17138 may contact the edges of the wafers #1708 when the wafers 1708 are placed on the wafer supports 1738 and start to turn, causing the wafers 1708 to move radially inward towards the center axis 1752 while avoiding or reducing the potential that the wafer edge will engage in sliding contact with the wafer edge contact interfaces (which may generate particulate contamination). Each roller 17138 may, for example, have a surface closest to the corresponding rotational axis for the wafer support 1738 supporting that roller 17138 that is located at a distance from the corresponding rotational axis 1754 for that wafer support 1738 that is substantially equal to one half of D, the diameter of the wafer 1708.

In some implementations, the one or more wafer edge contact interfaces that are included in each wafer support 1738 may be designed so as to contact the wafer 1708 at at least two points of contact that act to act to limit radial outward movement of the wafer 1708 during rotation of the indexer arms 1740 at a first angular rate (or higher) and while the wafer supports 1738 are in the first rotational position. The first angular rate, for example, may be a rotational rate that causes centrifugal forces to be exerted on the wafers 1708 that exceed the friction forces that may exist between the wafer supports 1738 and the wafers 1708.

In some implementations, the at least two points of contact between the one or more wafer edge contact interfaces of each wafer support 1738 and the wafer 1708 may, for example both or all lie within a corresponding sector of arc 17146 relative to the rotational axis 1754 of that wafer support 1738. The sector of arc 17146 may, for example, be a 90°, 60°, or 30° sector of arc. Such implementations may position the wafer edge contact interfaces of each wafer support 1738 such that they are close enough together that it is possible to pass the portion of each wafer support 1738 that includes the wafer edge contact interfaces in between, for example, lift pins that may be extended from the pedestals 1710 to facilitate loading the wafers 1708 onto or off of the wafer supports 1738.

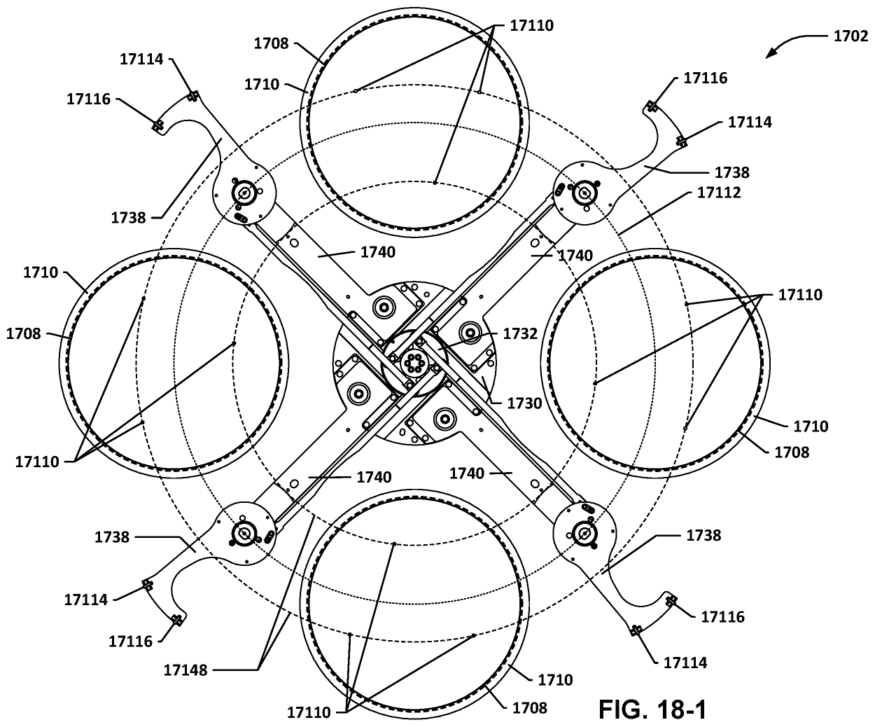

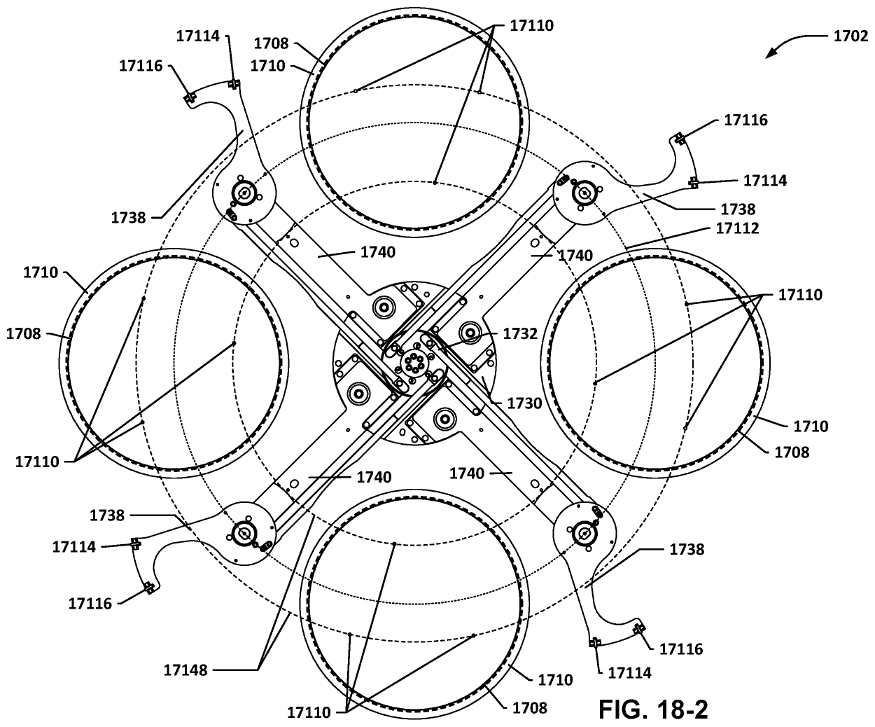

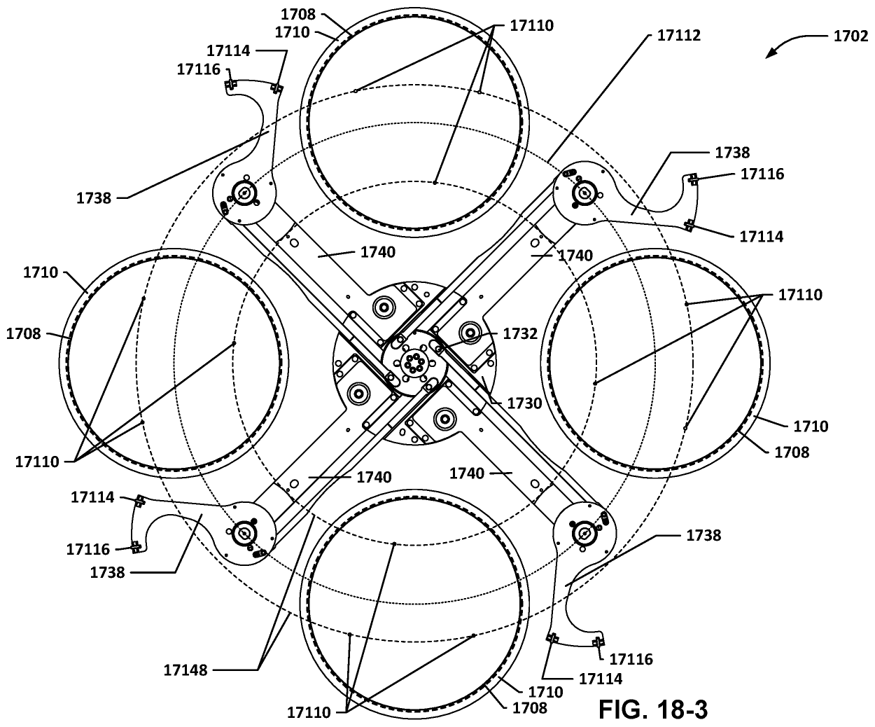

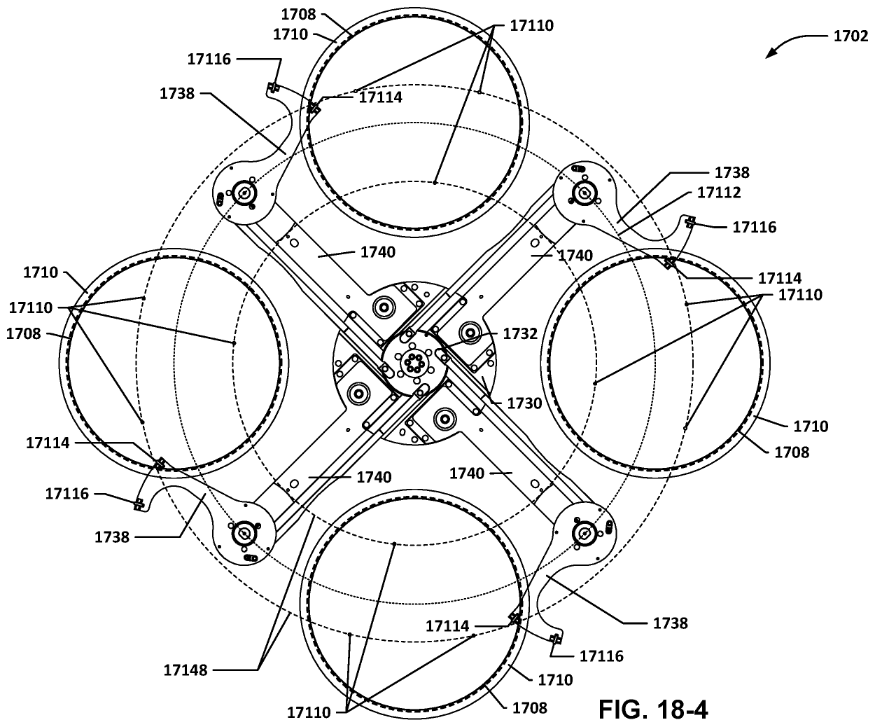

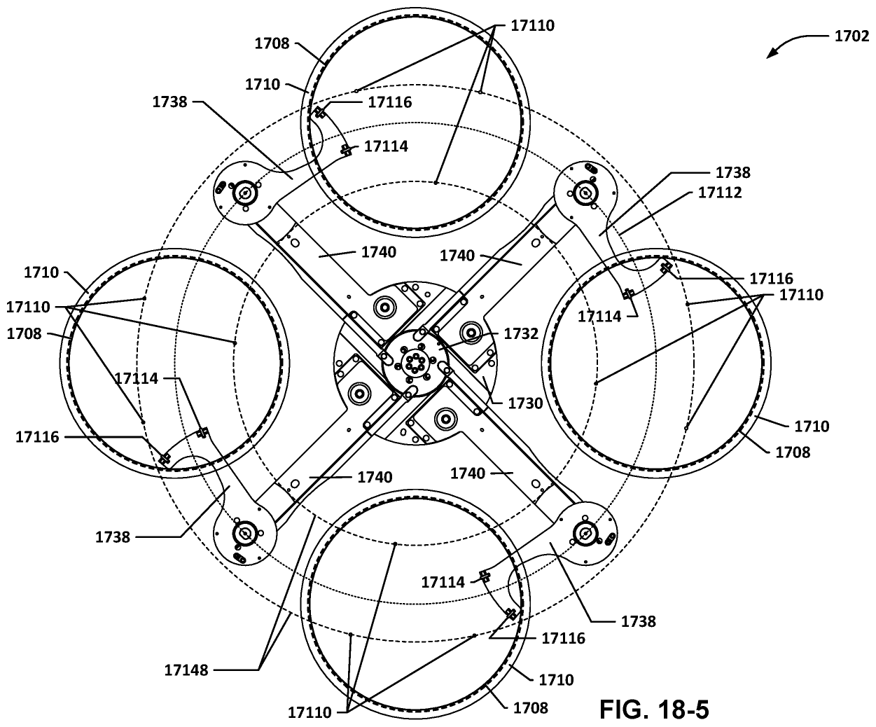

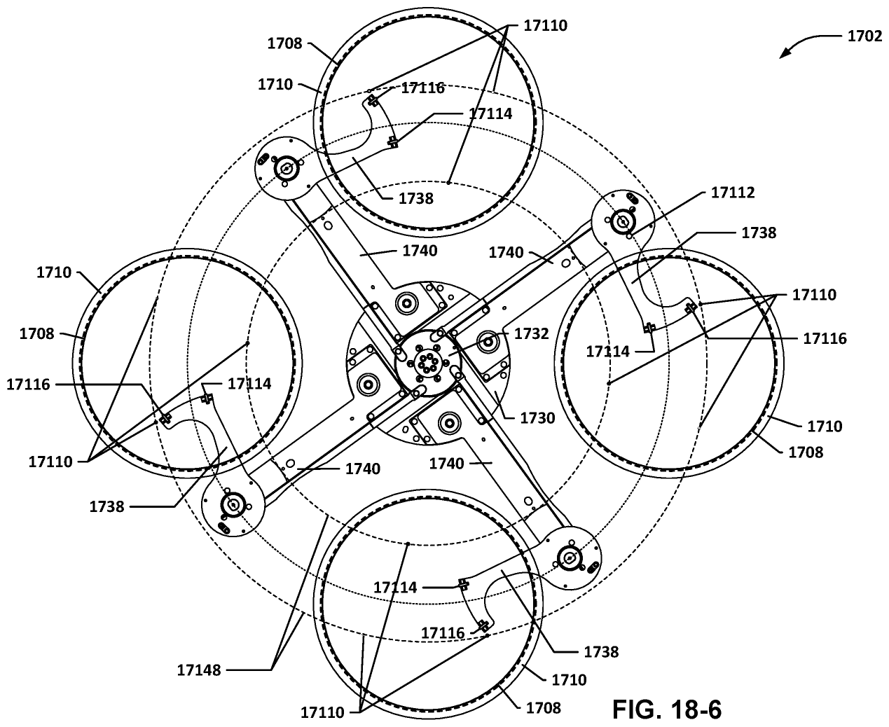

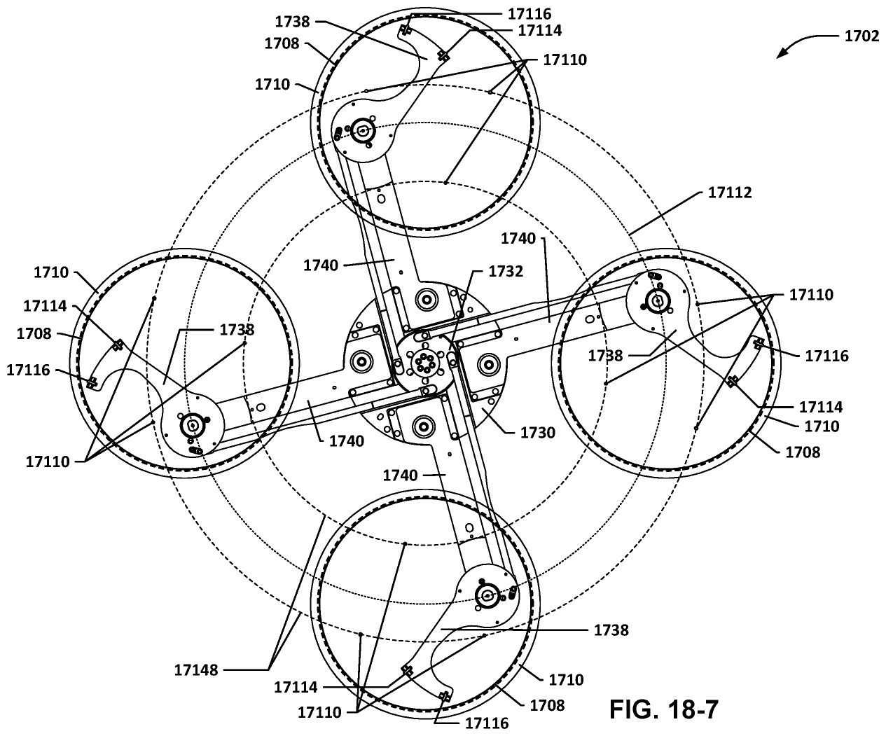

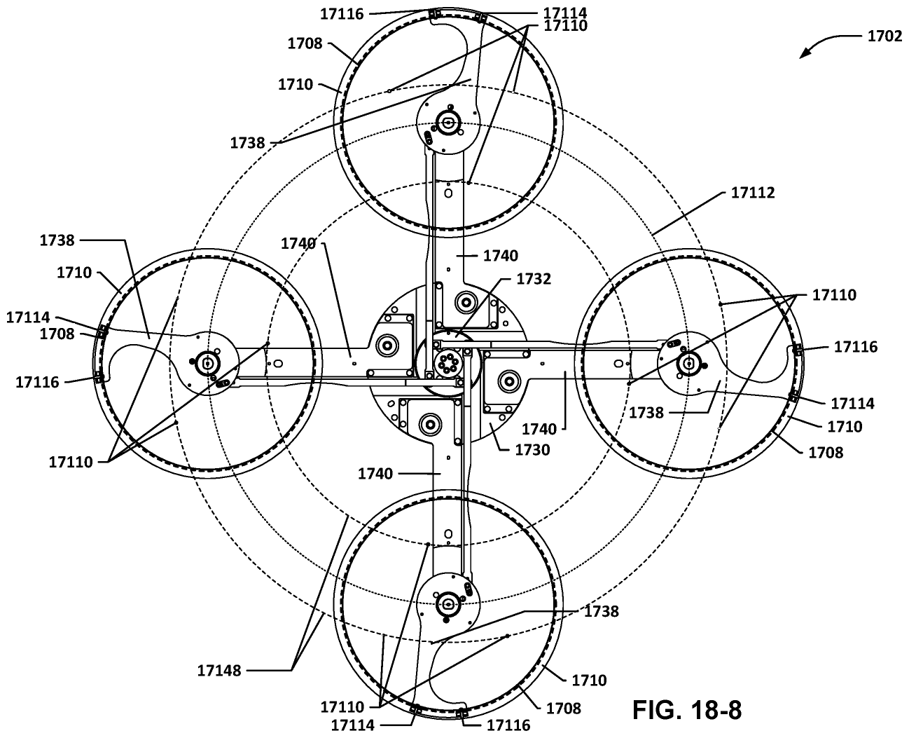

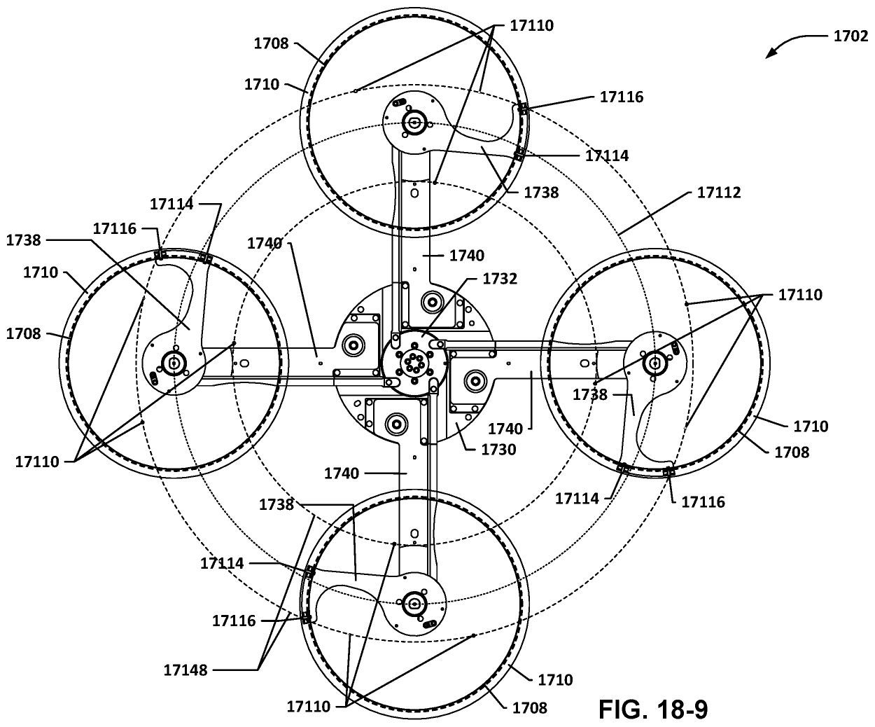

FIGS. 18-1 through 18-9 depict top views of the rotational indexer of FIG. 17 in various states of operation. In FIG. 18-1, the rotational indexer 1702 is shown with the first hub 1730 in a rotational position that placers each indexer arm 1740 at a location circumferentially interposed between two adjacent pedestals 310. The wafer supports 1738 are all shown as being in the second rotational positions relative to the indexer arms 1740. As shown in FIG. 18-1, each pedestal 1710 may have a wafer 1708 supported thereupon. Each pedestal 1710 may have a plurality of lift pins 17110 associated therewith that may, through vertical movement of the pedestals 1710 and/or the lift pins 17110, be transitioned between a plurality of states that includes at least one state in which the lift pins 17110 protrude from the pedestal 1710 and at least one state in which the lift pins 17110 do not protrude from the pedestal 1710.

The lift pins 17110 of each pedestal 1710 may define at least two circles 17148 that are centered on the center axis 1752. For example, one of the circles 17148 may pass through one of the lift pins 17110 associated with a pedestal 1710, while the other of the circles 17148 may pass through another of the lift pins 17110 associated with the pedestal 1710. Generally speaking, the two circles 17148 may be significantly different in diameter and may, in some cases, represent the largest and smallest such circles that can be drawn given the constraints discussed above. The circles 17148 may, for example, define an annular corridor through which the portion of the wafer supports 1738 having the wafer edge contact interfaces may be maneuvered, e.g., via suitable rotation of the wafer supports 1738 relative to the indexer arms 1740 during or before the rotation of the indexer arms 1740, in order to allow the wafer supports 1738 to be moved into locations in which the rotational axes 1754 thereof are nominally centered over each pedestal 1710 without colliding with the lift pins 17110, which may be in an extended state relative to the pedestals 1710.

For example, with the rotational indexer 1702 in the state shown in FIG. 18-1, the lift pins 17110 and pedestals 1710 may be caused to enter into a state in which the lift pins 17110, including a first set of lift pins 17110 associated with a first pedestal 1710 of the pedestals 1710, extend from the pedestals 1710, thereby lifting the wafers 1708 that may be supported on the pedestals 1710 off of the pedestals 1710 and into the air. The wafers 1708 may be raised high enough off of the pedestals 1710 that there is sufficient space for the indexer arms 1740 and wafer supports 1738 to pass in between the wafers 1708 and the pedestals 1710.

In the configuration shown in FIG. 18-1, the wafer supports 1738 are shown extended past the outermost of the circles 17148, generally in the position they would be in when used to support a wafer 1708 during rotation of the indexer arms 1740 about the center axis 1752, e.g., with the first wafer edge contact interface 17114 and the second wafer edge contact interface 17116 positioned outside of the circles 17148. This generally puts the wafer supports 1738 in a position that is generally equidistant between adjacent pedestals 1710, which may reduce non-uniformities in processing that is performed on the wafers 1708 with the rotational indexer 1702 in the position shown. However, if the indexer arms 1740 were to be caused to rotate about the center axis 1752 so as to move the wafer supports 1738 so as to be positioned over the centers of the pedestals 1710, the wafer supports 1738 would collide with some of the lift pins 17110.

To avoid such collisions, the wafer supports 1738 may be caused to rotate into the first rotational positions before rotating the indexer arms 1740 such that the wafer supports 1738 are positioned above the centers of the pedestals 1710. This is illustrated in FIGS. 18-2 through 18-5. As can be seen, the wafer supports 1738 have been caused to rotate about their respective rotational axes 1754, e.g., from the second rotational position to the first rotational position. This causes the portions of the wafer supports 1738 that have the wafer edge contact interfaces to be positioned within the outermost of the circles 17148. Thus, when the indexer arms 1740 are subsequently rotated so as to place the wafer supports 1738 underneath the wafers 1708, such movement may be accomplished without collision between the lift pins 17110 and the wafer supports 1738, as illustrated in FIGS. 18-6 through 18-9.

In FIGS. 18-6 and 18-7, the wafer supports 1738 are rotated back into the second rotational positions as the indexer arms 1740 are rotated into positions with the rotational axes 1754 of the wafer supports 1738 centered on the pedestals 1710. The lift pins 17110 and the pedestals 1710 may then be caused to transition to a state in which the lift pins 17110, including the first set of lift pins 17110 associated with the first pedestal 1710 of the pedestals 1710, do not protrude from an upper surface of the pedestals 1710, thereby causing the wafers 1708 to be placed onto the wafer supports 1738. The indexer arms 1740 may then be caused to rotate about the center axis 1752 by 360°/N (where N is the number of indexer arms, e.g., four in this example) to move each wafer 1708 from positions over the pedestals 1710 that are shown in FIG. 18-8 to positions over the pedestals adjacent thereto. Such rotation may be done at a rotational rate that generates centrifugal forces that exceed the friction forces that may exist between the wafer supports 1738 and the wafers 1708 since radial slip of the wafers 1708 due to such rotation may be prevented by the wafer edge contact interfaces.

If desired, the wafer supports 1738 may then be caused to rotate, e.g., by 360°/N, relative to the indexer arms 1740, e.g., to cause the wafers 1708 to rotate about the rotational axes 1754, e.g., into the position shown in FIG. 18-9, prior to causing the lift pins 17110 and the pedestals 1710 to be caused to transition to a state in which the lift pins 17110 protrude from the upper surfaces of the pedestals 1710, thereby lifting the wafers 1708 off of the wafer supports 1738. The indexer arms 1740 may then be caused to rotate back into the positions shown in FIG. 18-1 and the lift pins 17110 and the pedestals 1710 may be caused to transition back to a state in which the lift pins 17110 do not protrude from the upper surfaces of the pedestals 1710, thereby causing the wafers 1708 to be placed onto the pedestals 1710. This may act to help even out non-uniformities that may arise on the wafers 1708 as a result of processing performed on the wafers 1708 when such rotation is not performed in between transfers of the wafers 1708 between the pedestals 1710.

It is also the case that the indexer arms 1740 may be caused to rotate from the position shown in FIG. 18-6 directly into the position shown in FIG. 18-9. In such implementations, the wafers 1708 may then be placed on the wafer supports 1738 and the wafer supports 1738 then rotated into the positions shown in FIG. 18-8 before rotating the indexer arms 1740 to move the wafers 1708 into position above different ones of the pedestals 1710. The wafers may then be removed from the wafer supports 1738, as discussed above, and the indexer arms 1740 rotated into the position shown in FIG. 18-1 before placing the wafers 1708 on the pedestals 1710.

Movements such as those discussed above may be performed at the direction of a controller, e.g., similar to the controller discussed earlier, which may be configured to control the various motors that may be actuated in order to cause the rotational indexer 1702 and wafer supports 1738 to move as discussed above.

It will be appreciated that while the examples discussed herein have used a linkage-based actuation system that allows for all of the wafer supports to be rotated simultaneously in response to relative rotation between a first hub and a second hub, it will be understood that other implementations may use different actuation systems, e.g., indexers in which the wafer supports are each driven via belt systems (instead of linkage systems), chain drives, shaft and gear drives, or even discrete motors located at the ends of the indexer arms. The concepts discussed herein may be employed in rotational indexers regardless of what drive mechanism is used to induce rotation of the wafer supports relative to the indexer arms, and it is to be understood that the present disclosure extends to such alternative designs as well. It will also be understood that the concepts discussed herein may be implemented in indexers having fewer or greater numbers of indexer arms and wafer supports, and that the number of wafer supports need not necessarily match the number of pedestals in a semiconductor processing tool having such a rotational indexer. It will also be understood that while the examples discussed herein have featured implementations with radial symmetry, e.g., circular arrays of indexer arms and wafer supports, other implementations may lack such radial symmetry. Such systems are still, however, within the scope of the present disclosure.

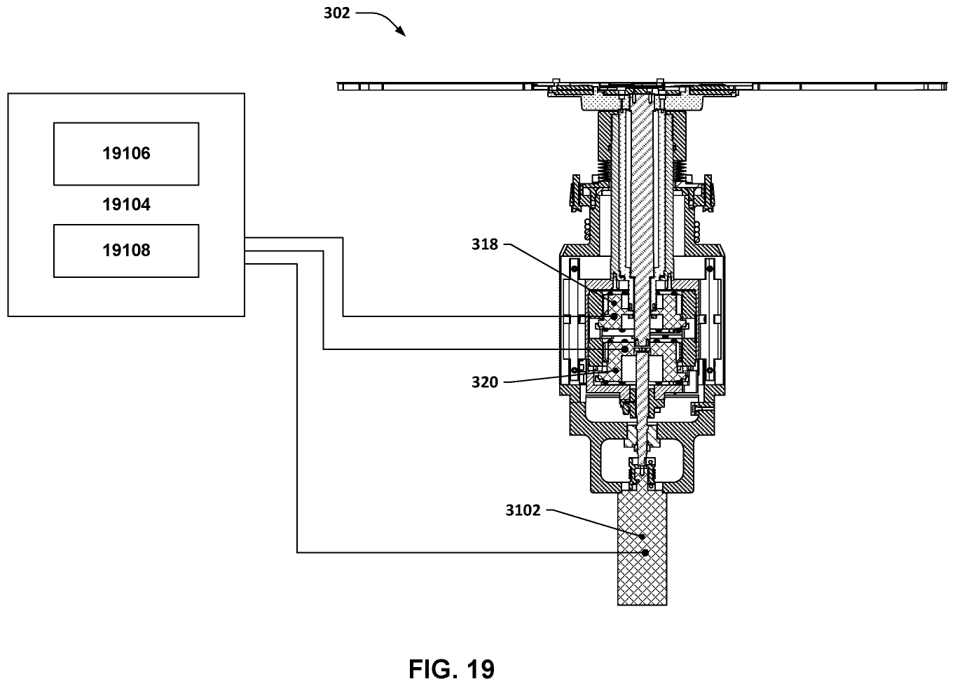

As discussed above, in some implementations, a controller may be part of the rotational indexer systems discussed herein. FIG. 19 depicts a schematic of an example controller 19104 with one or more processors 19106 and a memory 19108, which may be integrated with electronics for controlling the operation of the first motor 318, the second motor 320, and, if present, the third motor 3102 during wafer transfer operations. The controller, depending on the processing requirements and/or the type of system, may be programmed to control any of the processes disclosed herein, such as processes for controlling the rotational indexer, as well as other processes or parameters not discussed herein, such as the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a chamber and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example rotational indexers according to the present disclosure may be mounted in or part of semiconductor processing tools with a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

It is to be understood that the term “set,” unless further qualified, refers to a set of one or more items—it does not require that multiple items be present unless there is further language that implies that it does. For example, a “set of two or more items” would be understood to have, at a minimum, two items in it. In contrast, a “set of one or more items” would be understood to potentially only have one item in it. In a similar vein, it is to be understood that the term “each” may be used herein to refer to each member of a set, even if the set only includes one member. The term “each” may also be used in the same manner with implied sets, e.g., situations in which the term set is not used but other language implies that there is a set. For example, “each item of the one or more items” is to be understood to be equivalent to “each item in the set of one or more items.”

It is to be understood that the above disclosure, while focusing on a particular example implementation or implementations, is not limited to only the discussed example, but may also apply to similar variants and mechanisms as well, and such similar variants and mechanisms are also considered to be within the scope of this disclosure.

What is claimed is:

1. An apparatus comprising:
a rotational indexer, the rotational indexer including:
a base;
a first hub; and
N indexer arm assemblies, each indexer arm assembly including a) a wafer support and b) an indexer arm having a proximal end fixedly connected with the first hub and a distal end that supports the wafer support for that indexer arm, wherein:
each wafer support is configured to be rotatable about a corresponding rotational axis located at the distal end of the indexer arm that supports that wafer support and between a first rotational position relative to the indexer arms and a second rotational position relative to the indexer arms,
the first hub is configured to be rotatable about a center axis and between at least a first angular position relative to the base and a second angular position relative to the base,
the first angular position and the second angular position are 360°/N apart,
each wafer support has at least three corresponding wafer edge contact interfaces including a corresponding first wafer edge contact interface, a corresponding second wafer edge contact interface, and a corresponding third wafer edge contact interface,
each wafer edge contact interface is, when the wafer supports are in the first rotational positions relative to the indexer arm assemblies and the wafer supports are viewed along a direction parallel to the center axis, located outside of a plurality of circular reference regions that each have a center positioned along a circular path centered on the center axis, are each positioned between a different adjacent pair of the indexer arm assemblies, and that each have a diameter D, and
each wafer edge contact interface is, when the wafer supports are in the second rotational positions relative to the indexer arm assemblies and the wafer supports are viewed along a direction parallel to the center axis, located at least partially within one of the circular reference regions.

2. The apparatus of claim 1, wherein:
the first wafer edge contact interfaces are, when the wafer supports are in the first rotational positions relative to the indexer arm assemblies and the wafer supports are viewed along a direction parallel to the center axis, all located at least partially within a regular N-sided polygonal region that is circumscribed about the circular path and centered on the center axis,
each corner of the regular polygonal region lies along an axis that passes through the center axis and one of the rotational axes of the wafer supports,
the second wafer edge contact interfaces and the third wafer edge contact interfaces are, when the wafer supports are in the first rotational positions relative to the indexer arm assemblies and the wafer supports are viewed along a direction parallel to the center axis, all located at least partially outside of the regular N-sided polygonal region,
the first wafer edge contact interfaces and the second wafer edge contact interfaces are, when the wafer supports are in the second rotational positions relative to the indexer arm assemblies and the wafer supports are viewed along a direction parallel to the center axis, all located at least partially outside of the regular N-sided polygonal region, and
the third wafer edge contact interfaces are, when the wafer supports are in the second rotational positions relative to the indexer arm assemblies and the wafer supports are viewed along a direction parallel to the center axis, all located at least partially within the regular N-sided polygonal region.

3. The apparatus of claim 2, wherein:
the first wafer edge contact interfaces are, when the wafer supports are in the first rotational positions relative to the indexer arm assemblies, all located within the regular N-sided polygonal region,
the second wafer edge contact interfaces and the third wafer edge contact interfaces are, when the wafer supports are in the first rotational positions relative to the indexer arm assemblies, all located outside of the regular N-sided polygonal region,
the first wafer edge contact interfaces and the second wafer edge contact interfaces are, when the wafer supports are in the second rotational positions relative to the indexer arm assemblies, all located outside of the regular N-sided polygonal region, and
the third wafer edge contact interfaces are, when the wafer supports are in the second rotational positions relative to the indexer arm assemblies, all located within the regular N-sided polygonal region.

4. The apparatus of claim 1, wherein:
each wafer support includes a corresponding top surface, and
each wafer edge contact interface includes a corresponding wafer support surface that is positioned at an elevation lower than the corresponding top surface of the wafer support having that wafer edge contact interface.

5. An apparatus comprising:
a rotational indexer, the rotational indexer including:
a base;
a first hub; and
N indexer arm assemblies, each indexer arm assembly including a) a wafer support and b) an indexer arm having a proximal end fixedly connected with the first hub and a distal end that supports the wafer support for that indexer arm, wherein:
each wafer support is configured to be rotatable about a corresponding rotational axis located at the distal end of the indexer arm that supports that wafer support and between at least a first rotational position relative to the indexer arms and a second rotational position relative to the indexer arms,
the first hub is configured to be rotatable about a center axis and between at least a first angular position relative to the base and a second angular position relative to the base,
the first angular position and the second angular position are 360°/N apart, and
each wafer support:
is configured to support a semiconductor wafer of diameter D from below when the semiconductor wafer is placed on that wafer support, and
has one or more corresponding wafer edge contact interfaces configured to limit radial outward movement of the semiconductor wafer due to centrifugal force when the first hub is caused to rotate about the center axis at a first angular rate while the semiconductor wafer is supported by that wafer support and that wafer support is in the second relative rotational position.

6. The apparatus of claim 5, wherein the one or more corresponding wafer edge contact interfaces of each wafer support limit radial outward movement of the semiconductor wafer by way of at least two points of contact between the one or more corresponding wafer edge contact interfaces and the semiconductor wafer due to centrifugal force when the first hub is caused to rotate about the center axis at the first angular rate while the semiconductor wafer is supported by that wafer support and that wafer support is in the second rotational position.

7. The apparatus of claim 6, wherein the one or more corresponding wafer edge contact interfaces of each wafer support includes at least a first wafer edge contact interface and a second wafer edge contact interface.

8. The apparatus of claim 7, wherein, for each wafer support, the corresponding first wafer edge contact interface and the corresponding second wafer edge contact interface are both positioned within a 90° sector of arc relative to the corresponding rotational axis of that wafer support.

9. The apparatus of claim 8, wherein, for each wafer support, the corresponding first wafer edge contact interface and the corresponding second wafer edge contact interface are both positioned within a 60° sector of arc relative to the corresponding rotational axis of that wafer support.

10. The apparatus of claim 9, wherein, for each wafer support, the corresponding first wafer edge contact interface and the corresponding second wafer edge contact interface are both positioned within a 30° sector of arc relative to the corresponding rotational axis of that wafer support.

11. The apparatus of claim 7, wherein each wafer edge contact interface includes a corresponding roller configured to rotate relative to the indexer arms.

12. The apparatus of claim 11, wherein each roller is configured to rotate relative to the indexer arms and about a corresponding roller axis that is parallel to a reference plane that is perpendicular to the center axis.

13. The apparatus of claim 11, wherein each roller of each wafer support has a surface closest to the corresponding rotational axis for that wafer support that is located at a distance from the corresponding rotational axis for that wafer support that is substantially equal to one half of D.

14. The apparatus of claim 7, wherein each wafer support includes a plurality of protrusions extending upward from an upper surface of that wafer support and configured to support the semiconductor wafer of diameter D from below when the semiconductor wafer is placed on that wafer support.

15. The apparatus of claim 14, further comprising N pedestals and a first set of lift pins associated with a first pedestal of the N pedestals, wherein:
the wafer supports, when in the first rotational position, are oriented such that the first wafer edge contact interface and the second wafer edge contact interface of a first wafer support of the N wafer supports lies within a circle centered on the center axis and passing through at least one of the lift pins in the first set of lift pins, and
the wafer supports, when in the second rotational position, are oriented such that the first wafer edge contact interface and the second wafer edge contact interface of the first wafer support lie outside of the circle.

16. The apparatus of claim 15, further comprising a controller configured to:
a) cause the first set of lift pins and the first pedestal to enter a first state in which the first set of lift pins protrude from an upper surface of the first pedestal,
b) cause the N wafer supports to rotate into the first rotational positions after (a),
c) cause the first set of lift pins and the first pedestal to enter a second state in which the first set of lift pins do not protrude from the upper surface of the first pedestal, and
d) cause the first hub to rotate about the center axis at least after (b) is started such that each wafer support is above a corresponding one of the pedestals prior to (c).

17. The apparatus of claim 16, wherein the controller is further configured to cause at least part of (b) and (d) to occur simultaneously.

18. The apparatus of claim 16, wherein the controller is further configured to:
e) cause, after (c), the first hub to further rotate about the center axis by 360°/N, and
f) cause, after (e), a second set of lift pins associated with a second pedestal of the N pedestals to enter a first state in which the second set of lift pins protrude from an upper surface of the second pedestal.

19. The apparatus of claim 18, wherein the controller is further configured to cause the wafer supports to be in the second rotational positions during (e).

20. The apparatus of claim 18, wherein the controller is further configured to:
g) cause the N wafer supports to rotate about the corresponding rotational axes relative to the indexer arms in between (c) and (f).
